(19) United States
(12) Patent Application Publication
(10) Pub. No.: US 2026/0005076 A1
(43) Pub. Date: Jan. 1, 2026

(54) DEVICE COMPRISING A PACKAGE, A LID FRAME, A THERMAL INTERFACE MATERIAL AND AN ADHESIVE

(71) Applicant: QUALCOMM Incorporated, San Diego, CA (US)

(72) Inventors: Yanmei SONG, San Diego, CA (US); Chung-Yi CHOU, Kaohsiung City (TW); Sun Woong YUN, San Diego, CA (US); Jingyi HUANG, San Diego, CA (US); William STONE, San Diego, CA (US)

(21) Appl. No.: 18/759,143

(22) Filed: Jun. 28, 2024

(51) Int. Cl. H01L 23/043; H01L 23/10; H01L 23/31; H01L 23/373

(52) U.S. Cl. CPC H01L 23/043; H01L 23/10; H01L 23/3157; H01L 23/373

(57) ABSTRACT

A device comprising a substrate, a package coupled to the substrate, and a lid frame coupled to the substrate. The package comprises a first integrated device and an encapsulation layer that at least partially encapsulates the first integrated device. The lid frame is further coupled to the first integrated device through a thermal interface material. The lid frame is further coupled to the encapsulation layer through an adhesive.

### FIELD

Various features relate to a device with a package and a lid frame.

### BACKGROUND

A package may include a substrate, an interposer and/or integrated devices. These components are coupled together to provide a package that may perform various electrical functions. There is an ongoing need to provide reliable and/or better performing packages. Moreover, there is also an ongoing need to reduce the overall size of the packages and associated components.

### SUMMARY

Various features relate to a device with a package and a lid frame.

One example provides a device comprising a substrate, a package coupled to the substrate, and a lid frame coupled to the substrate. The package comprises a first integrated device and an encapsulation layer that at least partially encapsulates the first integrated device. The lid frame is further coupled to the first integrated device through a thermal interface material. The lid frame is further coupled to the encapsulation layer through an adhesive.

Another example provides a device comprising a substrate; a package coupled to the substrate, and a lid frame coupled to the substrate. The package comprises package interposer, a first integrated device coupled to the package interposer; and a second encapsulation layer that at least partially encapsulates the first integrated device. The package interposer comprises a first metallization portion; a first encapsulation layer coupled to the first metallization portion; and a second metallization portion coupled to the first encapsulation layer. The lid frame is further coupled to the first integrated device through a thermal interface material. The lid frame is further coupled to the second encapsulation layer through an adhesive.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a device comprising a package, a lid frame, a thermal interface material and an adhesive.

FIG. 2A illustrates an exemplary plan view of a device comprising a package, a lid frame, a thermal interface material and an adhesive.

FIG. 2B illustrates an exemplary plan view of a device comprising a package, a lid frame, a thermal interface material and an adhesive.

FIG. 3 illustrates an exemplary cross sectional profile view of a device comprising a package, a lid frame, a thermal interface material and an adhesive.

FIG. 4 illustrates an exemplary cross sectional profile view of a device comprising a package, a lid frame, a thermal interface material and an adhesive.

FIG. 5A illustrates an exemplary plan view of a device comprising a package, a lid frame, a thermal interface material and an adhesive.

FIG. 5B illustrates an exemplary plan view of a device comprising a package, a lid frame, a thermal interface material and an adhesive.

FIGS. 6A-6E illustrate an exemplary sequence for fabricating a package comprising a trench capacitor device.

FIG. 7 illustrates an exemplary flow chart of a method for fabricating a package comprising a trench capacitor device.

FIGS. 8A-8E illustrate an exemplary sequence for fabricating a package comprising a trench capacitor device.

FIG. 9 illustrates an exemplary flow chart of a method for fabricating a package comprising a trench capacitor device.

FIGS. 10A-10B illustrate an exemplary sequence for fabricating a metallization portion.

FIG. 11 illustrates an exemplary flow chart of a method for fabricating a metallization portion.

FIG. 12 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a device comprising a substrate, a package coupled to the substrate, and a lid frame coupled to the substrate. The package comprises a first integrated device and an encapsulation layer that at least partially encapsulates the first integrated device. The lid frame is further coupled to the first integrated device through a thermal interface material. The lid frame is further coupled to the encapsulation layer through an adhesive. In some implementations, the use of the thermal interface material (TIM) and the adhesive helps provide a package that is efficient and effective at the dissipation of heat (e.g., improved thermal performance), while also providing improved mechanical adhesion and coupling with different components, resulting in a long lasting reliable device.

### Exemplary Device Comprising a Package, a Lid Frame, a Thermal Interface Material and an Adhesive

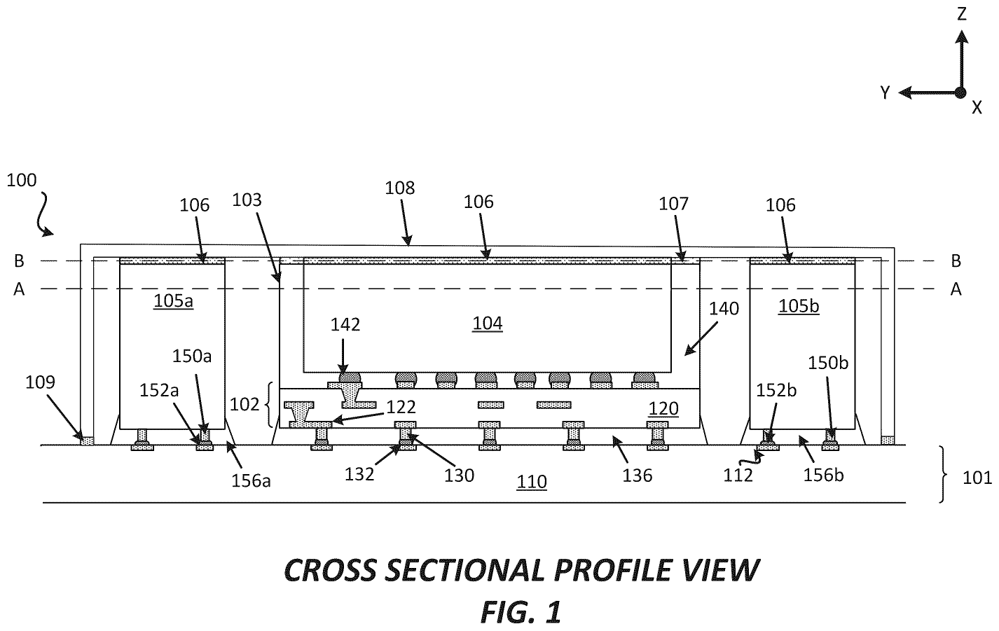

FIG. 1 illustrates a cross sectional profile view of a device 100 that includes a package, a lid frame, a thermal interface material and an adhesive. The device 100 includes a substrate 101, a package 103, an integrated device 105a, an integrated device 105b and a lid frame 108. The substrate 101 includes at least one dielectric layer 110 and a plurality of interconnects 112. The package 103 may be coupled to the substrate 101 through a plurality of pillar interconnects 130 and/or a plurality of solder interconnects 132. The plurality of pillar interconnects 130 and/or a plurality of solder interconnects 132 may be referred as a plurality of bump interconnects for the package 103.

The package 103 may include a substrate 102, an integrated device 104 and an encapsulation layer 140. The package 103 may include other integrated devices. The substrate 102 includes at least one dielectric layer 120 and a plurality of interconnects 122. The plurality of pillar interconnects 130 are coupled to the plurality of interconnects 122. The plurality of pillar interconnects 130 may be considered part of the substrate 102. The integrated device 104 is coupled to the plurality of interconnects 122 of the substrate 102 through at least a plurality of solder interconnects 142. The encapsulation layer 140 may be coupled to the substrate 102. The encapsulation layer 140 may at least partially encapsulate the integrated device 104. The encapsulation layer 140 may include a mold, a resin, an epoxy and/or a filler.

The integrated device 105a may be coupled to the substrate 101 through a plurality of pillar interconnects 150a and/or a plurality of solder interconnects 152a. The plurality of pillar interconnects 150a and/or a plurality of solder interconnects 152a may be referred as a plurality of bump interconnects for the integrated device 105a. An underfill 156a may be located between the substrate 101 and the integrated device 105a. In some implementations, the underfill 156a may include a composite material comprising an epoxy polymer with filler.

The integrated device 105b may be coupled to the substrate 101 through a plurality of pillar interconnects 150b and/or a plurality of solder interconnects 152b. The plurality of pillar interconnects 150b and/or a plurality of solder interconnects 152b may be referred as a plurality of bump interconnects for the integrated device 105a. An underfill 156b may be located between the substrate 101 and the integrated device 105b. In some implementations, the underfill 156b may include a composite material comprising an epoxy polymer with filler.

The integrated device 105a and/or the integrated device 105b may include a memory (e.g., memory die, memory integrated device). In some implementations, the integrated device 105a may include a first memory integrated device (e.g., first high density memory die, first high bandwidth memory). In some implementations, the integrated device 105b may include a second memory integrated device (e.g., second high density memory die, second high bandwidth memory). The integrated device 105a is configured to be electrically coupled to the package 103. The integrated device 105b is configured to be electrically coupled to the package 103.

The lid frame 108 is coupled to the substrate 101 through an adhesive 109. In some implementations, the lid frame 108 may be coupled to the substrate 101 through a thermal interface material (TIM). The lid frame 108 may include a thermally conductive material. The lid frame 108 may include a metal (e.g., Aluminum). The lid frame 108 may be configured as a heat spreader/heat sink. The lid frame 108 may be configured as a shield. The lid frame 108 laterally surrounds the package 103, the integrated device 105a and the integrated device 105b. The lid frame 108 may be coupled to a top portion of the package 103 through an thermal interface material (TIM) 106 and an adhesive 107. The lid frame 108 may be coupled to a top portion of the integrated device 105a through an thermal interface material (TIM) 106. The lid frame 108 may be coupled to a top portion of the integrated device 105b through an thermal interface material (TIM) 106. The thermal interface material (TIM) 106 may be located vertically between the lid frame 108 and a top portion of the integrated device 105a. The thermal interface material (TIM) 106 may be located vertically between the lid frame 108 and a top portion of the integrated device 105b. The thermal interface material (TIM) 106 may be located vertically between the lid frame 108 and a top portion of the integrated device 104. The thermal interface material (TIM) 106 may touch a portion of the lid frame 108 and a top portion of the integrated device 104. The adhesive 107 may be located vertically between the lid frame 108 and a top portion of the encapsulation layer 140. The adhesive 107 may touch another portion of the lid frame 108 and a top portion of the encapsulation layer 140 of the package 103. The adhesive 107 may include a sealant adhesive that may include a resin, an epoxy and/or a filler.

In some implementations, a thermal interface material (TIM) may include a high/higher thermal conductivity (relative to the adhesive) to better transfer heat from the integrated device to the lid frame and/or the heat spreader. Depending on the application and/or requirements of the integrated device(s), a thermal interface material (TIM) may have a thermal conductivity that is equal to or greater than 5 W/m·k (Watts per meter Kelvin). The thermal conductivity of a thermal interface material (TIM) may be changed by changing filler material from epoxy filler to metal filler and/or pre-form solder. In contrast, an adhesive is configured to provide as much stickiness between the lid frame and the package. Thus, adhesion strength is important for the adhesive. Moreover, the coefficient of thermal expansion (CTE) of the adhesive may be chosen to match the CTE of the package as closely as possible so avoid and/or minimize CTE mismatch. In some implementations, the adhesion strength of the adhesive may be equal to or greater than 2 Mpa (e.g., MegaPascal). The thermal interface material (TIM) and/or the adhesive may be dispense over the package in appropriate locations. The adhesive 107 is generally not going to have a thermal conductivity that is greater than the thermal conductivity of the thermal interface material (TIM) 106. In other words, the thermal conductivity of the thermal interface material (TIM) 106 is generally going to be higher than the thermal conductivity of the adhesive 107. In some implementations, the combination of the use of the thermal interface material (TIM) and the adhesive helps provide a package that is efficient and effective at the dissipation of heat (e.g., improved thermal performance), while also providing improved mechanical adhesion and coupling with different components, resulting in a long lasting reliable device. However, the thermal interface material (TIM) may have different thermal conductivity values and is not limited by the value mentioned above. Similarly, the adhesive may have different adhesion strength and is not limited by the value mentioned above. The values described is only an example of possible values for the thermal interface material (TIM) and/or the adhesive.

The configuration and/or use of the thermal interface material (TIM) and the adhesive provide a package that is mechanically coupled together in a robust way, resulting in less likelihood of delamination and/or degradation issues.

A stamping process may be used to fabricate the lid frame 108. Different implementations may have different sizes and/or shapes for the lid frame 108. In some implementations, the package 103, the integrated device 105a, the integrated device 105b and/or the lid frame 108 may be coupled to a board instead of a substrate 101.

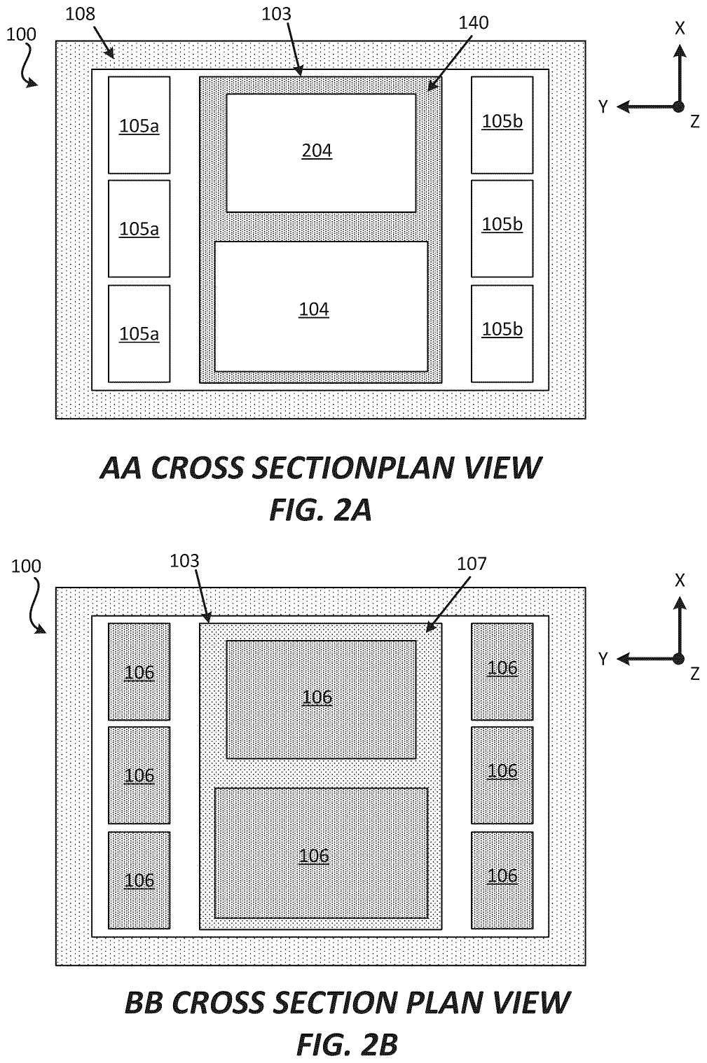

FIG. 2A illustrates an example of a plan view through cross section AA of the device 100 of FIG. 1. The device 100 includes a package 103, a lid frame 108, a plurality of integrated device 105a, and a plurality of integrated device 105b. The package 103 includes an integrated device 104, an integrated device 204, an encapsulation layer 140. The encapsulation layer 140 laterally surrounds the integrated device 104 and/or the integrated device 204.

FIG. 2B illustrates an example of a plan view through cross section BB of the device 100 of FIG. 1. The device 100 includes a package 103, a lid frame 108, a plurality of integrated device 105a, a plurality of integrated device 105b, the thermal interface material (TIM) 106 and the adhesive 107. The thermal interface material (TIM) 106 may touch and may be located vertically over (i) a top portion and/or a top surface of the integrated device 104, (ii) a top portion and/or a top surface of the integrated device 204, (iii) top portions and/or a top surfaces of the plurality of integrated devices 105a, and/or (iv) top portions and/or a top surfaces of the plurality of integrated devices 105b. The adhesive 107 may touch and may be located vertically over the encapsulation layer 140. The adhesive 107 may laterally surrounds the thermal interface material (TIM) 106 coupled to and touching the integrated device 104 and the integrated device 204. It is noted that the thermal interface material (TIM) 106 may touch the die substrate portion of an integrated device (e.g., back side of an integrated device). It is also noted that the thermal interface material (TIM) 106 may touch the encapsulation layer 140. It is also noted that the adhesive 107 may touch a die substrate portion of an integrated device (e.g., back side of an integrated device). It is noted that the vertical overlap of the thermal interface material (TIM) 106 with an integrated device does not need to be exact. Thus, the thermal interface material (TIM) 106 may vertically overlap with an integrated device and a portion of an encapsulation layer (e.g., 140). The thermal interface material (TIM) 106 does not need to vertically overlap with every portion of an integrated device. It is also noted that the vertical overlap of the adhesive 107 with an encapsulation layer does not need to be exact. Thus, the adhesive 107 may vertically overlap with an encapsulation layer (e.g., 140) and a portion of an integrated device (e.g., 104, 204). The adhesive 107 does not need to vertically overlap with every portion of an encapsulation layer. The above description of vertical overlaps of the thermal interface material (TIM) and/or the adhesive is applicable to any of the other packages described in the disclosure.

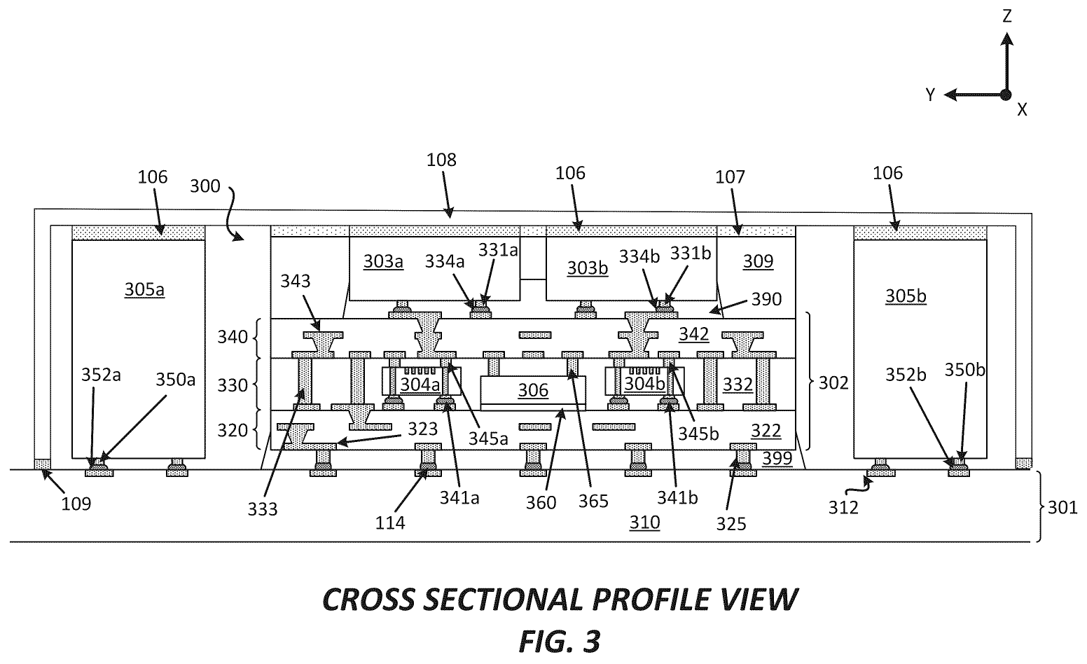

FIG. 3 illustrates a cross sectional profile view of a package 300 that includes a package interposer and a passive device. The package 300 is coupled to a board 301 through a plurality of solder interconnects 114. The board 301 includes at least one board dielectric layer 310 and a plurality of board interconnects 312. The board 301 may include a printed circuit board (PCB). In some implementations, instead of the board 301, the package 300 may be coupled to a substrate (e.g., laminated substrate) through the plurality of solder interconnects 114. The lid frame 108 may be coupled to the board 301 through an adhesive 109 (e.g., sealant adhesive that may include a resin, an epoxy and/or a filler). The package 300 includes a package interposer 302, an integrated device 303a, an integrated device 303b, an underfill 390 and an encapsulation layer 309. In some implementations, the integrated device 303a may include a first system on chip (SoC). In some implementations, the integrated device 303b may include a second system on chip (SoC).

The package interposer 302 may be a package substrate. The package interposer 302 includes a metallization portion 320, an encapsulated portion 330, a metallization portion 340, and a plurality of pillar interconnects 325. In some implementations, the metallization portion 320 may be a first metallization portion and the metallization portion 340 may be a second metallization portion. The encapsulated portion 330 is coupled to the metallization portion 320 and the metallization portion 340. The encapsulated portion 330 is located between the metallization portion 320 and the metallization portion 340. The metallization portion 320 includes at least one dielectric layer 322 and a plurality of metallization interconnects 323. The at least one dielectric layer 322 may include prepreg and/or polyimide. The metallization portion 340 includes at least one dielectric layer 342 and a plurality of metallization interconnects 343. The at least one dielectric layer 342 may include prepreg and/or polyimide. The plurality of pillar interconnects 325 are coupled to the plurality of metallization interconnects 323 of the metallization portion 320. The plurality of pillar interconnects 325 are coupled to the plurality of solder interconnects 114.

The encapsulated portion 330 includes an encapsulation layer 332 and a plurality of post interconnects 333. The plurality of post interconnects 333 may include a plurality of through mold vias (TMVs). The encapsulated portion 330 also includes a passive device 304a, a passive device 304b and a bridge 306. The passive device 304a, the passive device 304b and/or the bridge 306 may be located at least partially in the encapsulation layer 332. Thus, the encapsulation layer 332 may at least partially encapsulate the passive device 304a, the passive device 304b, the bridge 306 and/or the plurality of post interconnects 333. The passive device 304a and/or the passive device 304b may include a deep trench capacitor device.

The bridge 306 may include a silicon bridge. The bridge 306 may include a bridge substrate (e.g., silicon substrate, silicon bridge substrate) and a plurality of bridge interconnects. The bridge 306 may also include at least one bridge dielectric layer. The bridge 306 may include a plurality of post interconnects 365.

The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. A back side of the passive device 304a is coupled to the metallization portion 320 through a plurality of solder interconnects 341a (e.g., coupled to the plurality of metallization interconnects 323 through the plurality of solder interconnects 341a). A back side of the passive device 304b is coupled to the metallization portion 320 through a plurality of solder interconnects 341b (e.g., coupled to the plurality of metallization interconnects 323 through the plurality of solder interconnects 341b). A back side of the bridge 306 is coupled to the metallization portion 320 through an adhesive 360 (e.g., die attach film (DAF)).

The plurality of post interconnects 333 extend through the encapsulation layer 332. The plurality of post interconnects 333 are coupled to the metallization portion 320 and the metallization portion 340. For example, the plurality of post interconnects 333 may be coupled to (i) the plurality of metallization interconnects 323 of the metallization portion 320 and (ii) the plurality of metallization interconnects 343 of the metallization portion 340. The passive device 304a includes a plurality of post interconnects 345a. The plurality of post interconnects 345a are coupled to the passive device 304a and the plurality of metallization interconnects 343 of the metallization portion 340. The passive device 304b includes a plurality of post interconnects 345b. The plurality of post interconnects 345b are coupled to the passive device 304b and the plurality of metallization interconnects 343 of the metallization portion 340. The plurality of post interconnects 365 are coupled to the bridge 306 and the plurality of metallization interconnects 343 of the metallization portion 340.

The encapsulation layer 332, the passive device 304a, the passive device 304b, the bridge 306, the plurality of post interconnects 333, the plurality of post interconnects 345a, the plurality of post interconnects 345b and the plurality of post interconnects 365 are located between the metallization portion 320 and the metallization portion 340. The encapsulation layer 332 is coupled to the metallization portion 320 and the metallization portion 340. In some implementations, some of the metallization interconnects from the plurality of metallization interconnects 323 may be at least partially encapsulated by the encapsulation layer 332.

The integrated device 303a is coupled to a first surface of the metallization portion 340 through a plurality of pillar interconnects 331a and a plurality of solder interconnects 334a. The plurality of pillar interconnects 331a and/or the plurality of solder interconnects 334a may represent a plurality of bump interconnects. The integrated device 303b is coupled to a first surface of the metallization portion 340 through a plurality of pillar interconnects 331b and a plurality of solder interconnects 334b. The plurality of pillar interconnects 331b and/or the plurality of solder interconnects 334b may represent a plurality of bump interconnects.

An underfill 390 is located between the integrated device 303a and the package interposer 302. The underfill 390 is located between the integrated device 303b and the package interposer 302. In some implementations, the underfill 390 may include a composite material comprising an epoxy polymer with filler. An encapsulation layer 309 may be located over the package interposer 302. The package interposer 302 may be coupled to the underfill 390, the integrated device 303a, the integrated device 303b, the integrated device 305a, and/or the integrated device 305b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be different from the underfill 390. For example, the encapsulation layer 309 may include a different material and/or a different composition of material from the underfill 390. An underfill 399 may be located between the metallization portion 420 of the package interposer 402 and the board 301. The underfill 399 may be similar to the underfill 390.

The passive device 304a is configured to be electrically coupled to the integrated device 303a through the metallization portion 340. An electrical path between the integrated device 303a and the passive device 304a may include (i) a pillar interconnect from the plurality of pillar interconnects 331a, (ii) a solder interconnect from the plurality of solder interconnects 334a, (iii) at least one metallization interconnect from the plurality of metallization interconnects 343a, and/or (iv) a post interconnect from the plurality of post interconnects 345a.

The passive device 304b is configured to be electrically coupled to the integrated device 303b through the metallization portion 340. An electrical path between the integrated device 303b and the passive device 304b may include (i) a pillar interconnect from the plurality of pillar interconnects 331b, (ii) a solder interconnect from the plurality of solder interconnects 334b, (iii) at least one metallization interconnect from the plurality of metallization interconnects 343b, and/or (iv) a post interconnect from the plurality of post interconnects 345b.

In some implementations, an electrical path between the integrated device 303a and the integrated device 303b may include the metallization portion 340. In some implementations, an electrical path between the integrated device 303a and the integrated device 303b may include the metallization portion 340 and the bridge 306. For example, an electrical path between the integrated device 303a and the integrated device 303b may include (i) a pillar interconnect from the plurality of pillar interconnects 331a, (ii) a solder interconnect from the plurality of solder interconnects 334a, (iii) at least one metallization interconnect from the plurality of metallization interconnects 343, (iv) a post interconnect from the plurality of post interconnects 365, (v) the bridge 306, (vi) another post interconnect from the plurality of post interconnects 365, (vii) at least one other metallization interconnect from the plurality of metallization interconnects 343, (viii) a solder interconnect from the plurality of solder interconnects 334b and/or (ix) a pillar interconnect from the plurality of pillar interconnects 331b.

In some implementations, an electrical path between the metallization portion 320 and the metallization portion 340, may include at least one post interconnect from the plurality of post interconnects 333. In some implementations, an electrical path between the metallization portion 320 and the metallization portion 340, may include the passive device 304a. Thus, an electrical path between the metallization portion 320 and the metallization portion 340 may extend through the plurality of solder interconnects 341a, the passive device 304a and the plurality of post interconnects 345a. The plurality of post interconnects 345a may be considered part of the passive device 304a. In some implementations, an electrical path between the metallization portion 320 and the metallization portion 340, may include the passive device 304b. Thus, an electrical path between the metallization portion 320 and the metallization portion 240 may extend through the plurality of solder interconnects 341b, the passive device 304b and the plurality of post interconnects 345b. The plurality of post interconnects 345b may be considered part of the passive device 304b.

The integrated device 305a is coupled to the board 301 through a plurality of pillar interconnects 350a and a plurality of solder interconnects 352a. The integrated device 305a is coupled to the board 301 through a plurality of pillar interconnects 350b and a plurality of solder interconnects 352b. The integrated device 305a and/or the integrated device 305b may include a memory (e.g., memory die, memory integrated device). In some implementations, the integrated device 305a may include a first memory integrated device (e.g., first high density memory die). In some implementations, the integrated device 305b may include a second memory integrated device (e.g., second high density memory die). The integrated device 305a is configured to be electrically coupled to the integrated device 303a and/or the integrated device 303b. The integrated device 305b is configured to be electrically coupled to the integrated device 303a and/or the integrated device 303b.

The lid frame 108 is coupled to the board 301 through an adhesive 109. In some implementations, the lid frame 108 may be coupled to the board 301 through a thermal interface material (TIM). The lid frame 108 may include a thermally conductive material. The lid frame 108 may include a metal (e.g., Aluminum). The lid frame 108 laterally surrounds the package 300, the integrated device 305a and the integrated device 305b. The lid frame 108 may be coupled to a top portion of the package 300 through an thermal interface material (TIM) 106 and an adhesive 107. The lid frame 108 may be coupled to a top portion of the integrated device 305a through an thermal interface material (TIM) 106. The lid frame 108 may be coupled to a top portion of the integrated device 305b through an thermal interface material (TIM) 106. The thermal interface material (TIM) 106 may be located vertically between the lid frame 108 and a top portion of the integrated device 305a. The thermal interface material (TIM) 106 may be located vertically between the lid frame 108 and a top portion of the integrated device 305b. The thermal interface material (TIM) 106 may be located vertically between the lid frame 108 and a top portion of the integrated device 303a. The thermal interface material (TIM) 106 may touch a portion of the lid frame 108 and a top portion of the integrated device 303a. The thermal interface material (TIM) 106 may be located vertically between the lid frame 108 and a top portion of the integrated device 303b. The thermal interface material (TIM) 106 may touch a portion of the lid frame 108 and a top portion of the integrated device 303b. The adhesive 107 may be located vertically between the lid frame 108 and a top portion of the encapsulation layer 309. The adhesive 107 may touch another portion of the lid frame 108 and a top portion of the encapsulation layer 309 of the package 300. The adhesive 107 laterally surrounds the thermal interface material (TIM) 106 that is coupled to and touches (i) a top portion and/or a top surface of the integrated device 303a and/or (ii) a top portion and/or a top surface of the integrated device 303b. The adhesive 107 may include a sealant adhesive that may include a resin, an epoxy and/or a filler. It is noted that the thermal interface material (TIM) 106 may touch the die substrate portion of an integrated device (e.g., back side of an integrated device). It is also noted that the thermal interface material (TIM) 106 may touch the encapsulation layer 309. It is also noted that the adhesive 107 may touch a die substrate portion of an integrated device (e.g., back side of an integrated device).

This configuration and/or use of the thermal interface material (TIM) and the adhesive provide a package that is mechanically coupled together in a robust way, resulting in less likelihood of delamination and/or degradation issues.

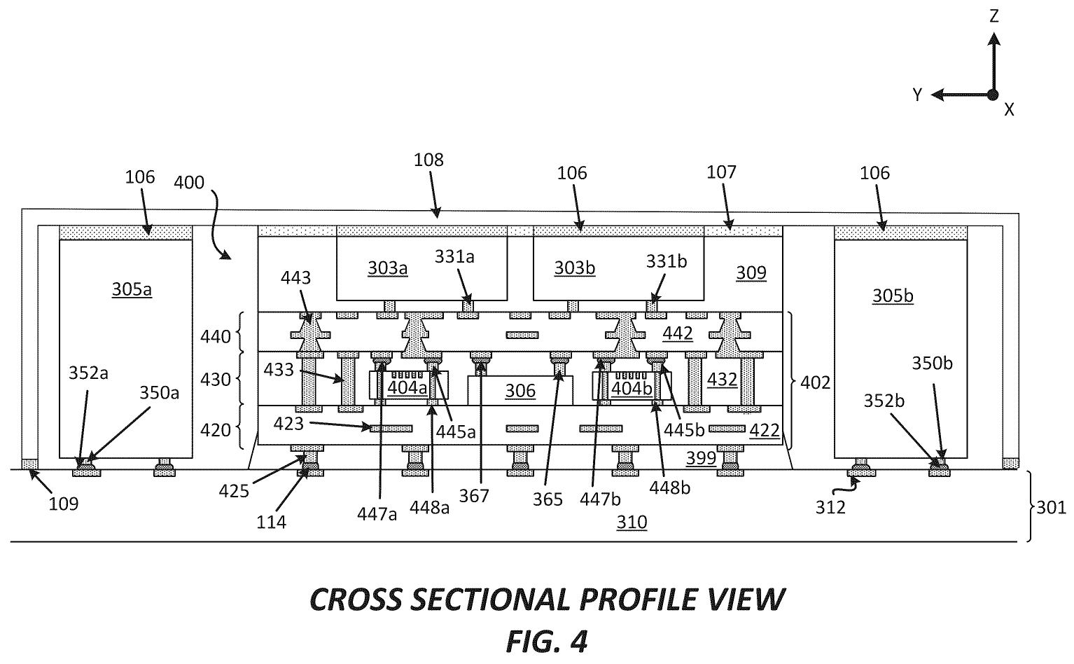

FIG. 4 illustrates a cross sectional profile view of a package 400 that includes a package interposer and a passive device. The package 400 is coupled to a board 301 through a plurality of solder interconnects 114. In some implementations, instead of the board 301, the package 400 may be coupled to a substrate (e.g., laminated substrate) through the plurality of solder interconnects 114. The lid frame 108 may be coupled to the board 301 through an adhesive 109 (e.g., die attach film (DAF)).

The package 400 is similar to the package 300 of FIG. 3, and may include similar components that are arranged in a similar manner as described for the package 300. The package 400 includes a package interposer 402, an integrated device 303a, an integrated device 303b, and an encapsulation layer 309. In some implementations, the integrated device 303a may include a first system on chip (SoC). In some implementations, the integrated device 303b may include a second system on chip (SoC).

The package interposer 402 may be a package substrate. The package interposer 402 includes a metallization portion 420, an encapsulated portion 430, a metallization portion 440, and a plurality of pillar interconnects 425. In some implementations, the metallization portion 420 may be a first metallization portion and the metallization portion 440 may be a second metallization portion. The encapsulated portion 430 is coupled to the metallization portion 420 and the metallization portion 440. The encapsulated portion 430 is located between the metallization portion 420 and the metallization portion 440. The metallization portion 420 includes at least one dielectric layer 422 and a plurality of metallization interconnects 423. The at least one dielectric layer 422 may include prepreg and/or polyimide. The metallization portion 440 includes at least one dielectric layer 442 and a plurality of metallization interconnects 443. The at least one dielectric layer 442 may include prepreg and/or polyimide. The plurality of pillar interconnects 425 are coupled to the plurality of metallization interconnects 423 of the metallization portion 420. The plurality of pillar interconnects 425 are coupled to the plurality of solder interconnects 114.

The encapsulated portion 430 includes an encapsulation layer 432 and a plurality of post interconnects 433. The encapsulated portion 430 also includes a passive device 404a, a passive device 404b, and a bridge 306. The passive device 404a, the passive device 404b, and/or the bridge 306 may be located at least partially in the encapsulation layer 432. Thus, the encapsulation layer 432 may at least partially encapsulate the passive device 404a, the passive device 404a, the bridge 306 and/or the plurality of post interconnects 433. The passive device 404a and/or the passive device 404b may include a deep trench capacitor device.

The bridge 306 may include a silicon bridge. The bridge 306 may include a bridge substrate (e.g., silicon substrate, silicon bridge substrate) and a plurality of bridge interconnects. The bridge 306 may also include at least one bridge dielectric layer. The bridge 306 may include a plurality of post interconnects 365.

The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. A back side of the passive device 404a is coupled to the metallization portion 420 through a plurality of interconnects 448a. A back side of the passive device 404b is coupled to the metallization portion 420 through a plurality of interconnects 448b. A back side of the bridge 306 is coupled to and touching the metallization portion 420.

The plurality of post interconnects 433 extend through the encapsulation layer 432. The plurality of post interconnects 433 may include a plurality of through mold vias (TMVs). The plurality of post interconnects 433 are coupled to the metallization portion 420 and the metallization portion 440. For example, the plurality of post interconnects 433 may be coupled to (i) the plurality of metallization interconnects 423 of the metallization portion 420 and (ii) the plurality of metallization interconnects 443 of the metallization portion 440.

The plurality of solder interconnects 447a may be coupled to the passive device 404a (e.g., coupled to the plurality of post interconnects 445a of the passive device 404a) and the plurality of metallization interconnects 443 of the metallization portion 440. The plurality of solder interconnects 447b may be coupled to the passive device 404b (e.g., coupled to the plurality of post interconnects 445b of the passive device 404b) and the plurality of metallization interconnects 443 of the metallization portion 440. The plurality of interconnects 448a are coupled to the plurality of metallization interconnects 423. The plurality of interconnects 448a may be considered part of the passive device 404a. The plurality of interconnects 448a may be considered part of and/or coupled to a back side of the passive device 404a. The plurality of interconnects 448b are coupled to the plurality of metallization interconnects 423. The plurality of interconnects 448b may be considered part of the passive device 404b. The plurality of interconnects 448b may be considered part of and/or coupled to a back side of the passive device 404b.

The front side of the passive device 404a faces in a direction of the metallization portion 440. The front side of the passive device 404a is coupled to metallization portion 440 through a plurality of solder interconnects 447a. The front side of the passive device 404b faces in a direction of the metallization portion 440. The front side of the passive device 404b is coupled to metallization portion 440 through a plurality of solder interconnects 447b.

The front side of the bridge 306 is coupled to the plurality of metallization interconnects 443 of the metallization portion 440 through the plurality of post interconnects 365 and the plurality of solder interconnects 367. The back side of the bridge 306 is coupled to and touch the metallization portion 420.

The encapsulation layer 432, the passive device 404a, the passive device 404b, the bridge 306, the plurality of post interconnects 433, the plurality of post interconnects 345a, the plurality of post interconnects 345b, and the plurality of post interconnects 365 are located between the metallization portion 420 and the metallization portion 440. The encapsulation layer 432 is coupled to the metallization portion 420 and the metallization portion 440. In some implementations, some of the metallization interconnects from the plurality of metallization interconnects 423 may be at least partially encapsulated by the encapsulation layer 432.

The integrated device 303a may be coupled to a first surface of the metallization portion 440 through a plurality of pillar interconnects 331a (and/or pad interconnects of the integrated device 303a). The integrated device 303b may be coupled to a first surface of the metallization portion 440 through a plurality of pillar interconnects 331b (and/or pad interconnects of the integrated device 303b).

An encapsulation layer 309 may be located over the package interposer 402. The package interposer 402 may be coupled to the integrated device 303a, the integrated device 303b and the encapsulation layer 309. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process.

The passive device 404a is configured to be electrically coupled to the integrated device 303a through the metallization portion 440. An electrical path between the integrated device 303a and the passive device 404a may include (i) a pillar interconnect from the plurality of pillar interconnects 331a, (ii) at least one metallization interconnect from the plurality of metallization interconnects 443a, (iii) a solder interconnect from the plurality of solder interconnects 447a and/or (iv) a post interconnect from the plurality of post interconnects 445a.

The passive device 404b is configured to be electrically coupled to the integrated device 303b through the metallization portion 440. An electrical path between the integrated device 303b and the passive device 404b may include (i) a pillar interconnect from the plurality of pillar interconnects 331b, (ii) at least one metallization interconnect from the plurality of metallization interconnects 443b, (iii) a solder interconnect from the plurality of solder interconnects 447b and/or (iv) a post interconnect from the plurality of post interconnects 445b.

In some implementations, an electrical path between the integrated device 303a and the integrated device 303b may include the metallization portion 440. In some implementations, an electrical path between the integrated device 303a and the integrated device 303b may include the metallization portion 440 and the bridge 306. For example, an electrical path between the integrated device 303a and the integrated device 303b may include (i) a pillar interconnect from the plurality of pillar interconnects 331a, (ii) at least one metallization interconnect from the plurality of metallization interconnects 443, (iii) a post interconnect from the plurality of post interconnects 365, (iv) the bridge 306, (v) another post interconnect from the plurality of post interconnects 365, (vi) at least one other metallization interconnect from the plurality of metallization interconnects 443, and/or (vii) a pillar interconnect from the plurality of pillar interconnects 331b.

In some implementations, an electrical path between the metallization portion 420 and the metallization portion 440, may include at least one post interconnect from the plurality of post interconnects 433. In some implementations, an electrical path between the metallization portion 420 and the metallization portion 440, may include the passive device 404a. Thus, an electrical path between the metallization portion 420 and the metallization portion 440 may extend through the plurality of interconnects 448a, the passive device 404a, the plurality of post interconnects 445a and the plurality of solder interconnects 447a. The plurality of post interconnects 445a and/or the plurality of interconnects 448a may be considered part of the passive device 404a. In some implementations, an electrical path between the metallization portion 420 and the metallization portion 440, may include the passive device 404b. Thus, an electrical path between the metallization portion 420 and the metallization portion 440 may extend through the plurality of interconnects 448b, the passive device 404b, the plurality of post interconnects 445b and the plurality of solder interconnects 447b. The plurality of post interconnects 445b and/or the plurality of interconnects 448b may be considered part of the passive device 404b.

The integrated device 305a is coupled to the board 301 through a plurality of pillar interconnects 350a and a plurality of solder interconnects 352a. The integrated device 305a is coupled to the board 301 through a plurality of pillar interconnects 350b and a plurality of solder interconnects 352b. The integrated device 305a and/or the integrated device 305b may include a memory (e.g., memory die, memory integrated device). In some implementations, the integrated device 305a may include a first memory integrated device (e.g., first high density memory die). In some implementations, the integrated device 305b may include a second memory integrated device (e.g., second high density memory die). The integrated device 305a is configured to be electrically coupled to the integrated device 303a and/or the integrated device 303b. The integrated device 305b is configured to be electrically coupled to the integrated device 303a and/or the integrated device 303b.

The lid frame 108 is coupled to the board 301 through an adhesive 109. In some implementations, the lid frame 108 may be coupled to the board 301 through a thermal interface material (TIM). The lid frame 108 may include a thermally conductive material. The lid frame 108 may include a metal (e.g., Aluminum). The lid frame 108 laterally surrounds the package 300, the integrated device 305a and the integrated device 305b. The lid frame 108 may be coupled to a top portion of the package 300 through an thermal interface material (TIM) 106 and an adhesive 107. The lid frame 108 may be coupled to a top portion of the integrated device 305a through an thermal interface material (TIM) 106. The lid frame 108 may be coupled to a top portion of the integrated device 305b through an thermal interface material (TIM) 106. The thermal interface material (TIM) 106 may be located vertically between the lid frame 108 and a top portion of the integrated device 305a. The thermal interface material (TIM) 106 may be located vertically between the lid frame 108 and a top portion of the integrated device 305b. The thermal interface material (TIM) 106 may be located vertically between the lid frame 108 and a top portion of the integrated device 303a. The thermal interface material (TIM) 106 may touch a portion of the lid frame 108 and a top portion of the integrated device 303a. The thermal interface material (TIM) 106 may be located vertically between the lid frame 108 and a top portion of the integrated device 303b. The thermal interface material (TIM) 106 may touch a portion of the lid frame 108 and a top portion of the integrated device 303b. The adhesive 107 may be located vertically between the lid frame 108 and a top portion of the encapsulation layer 309. The adhesive 107 may touch another portion of the lid frame 108 and a top portion of the encapsulation layer 309 of the package 300. The adhesive 107 laterally surrounds the thermal interface material (TIM) 106 that is coupled to and touches (i) a top portion and/or a top surface of the integrated device 303a and/or (ii) a top portion and/or a top surface of the integrated device 303b. The adhesive 107 may include a sealant adhesive that may include a resin, an epoxy and/or a filler. It is noted that the thermal interface material (TIM) 106 may touch the die substrate portion of an integrated device (e.g., back side of an integrated device). It is also noted that the thermal interface material (TIM) 106 may touch the encapsulation layer 309. It is also noted that the adhesive 107 may touch a die substrate portion of an integrated device (e.g., back side of an integrated device).

This configuration and/or use of the thermal interface material (TIM) and the adhesive provide a package that is mechanically coupled together in a robust way, resulting in less likelihood of delamination and/or degradation issues.

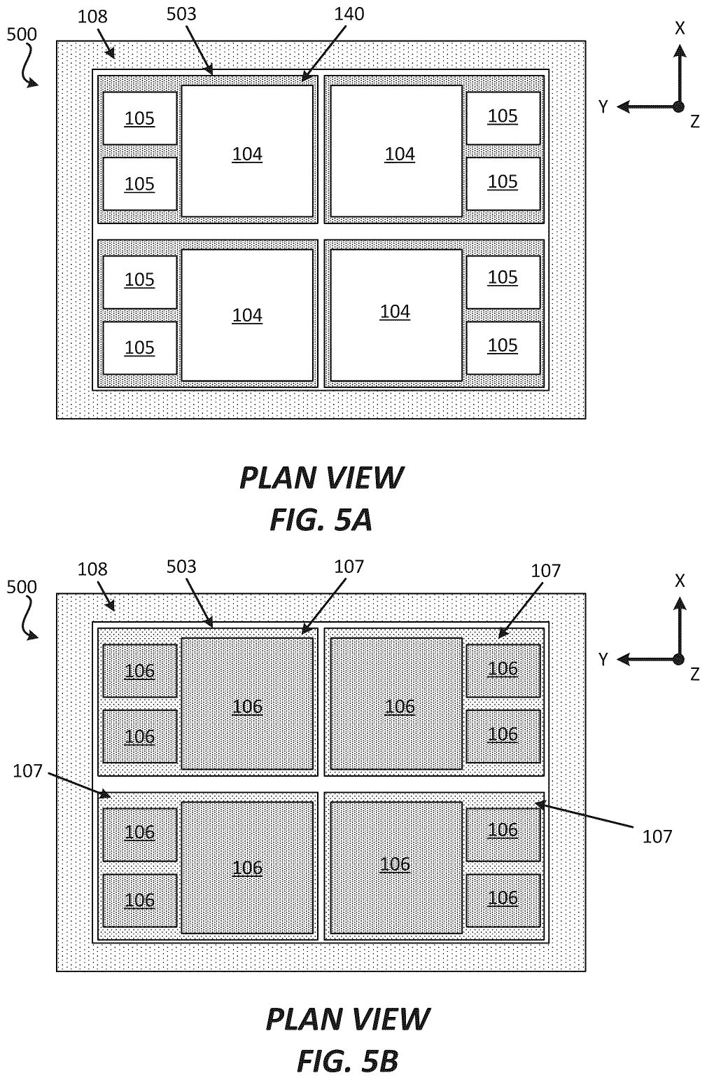

FIG. 5A illustrates an example of a plan view of a device 500 that includes a plurality of packages 503 and a lid frame 108. Each package from the plurality of packages 503 may include an integrated device 104 and a plurality of integrated devices 105 and an encapsulation layer 140. The encapsulation layer 140 may at least partially encapsulate the integrated device 104 and the plurality of integrated device 105. The encapsulation layer 140 may laterally surround the integrated device 104 and the plurality of integrated device 105. Each package from the plurality of packages 503 may include a substrate, a metallization portion, or a package interposer as described in FIGS. 1, 3 and/or 4. The lid frame 108 laterally surrounds the plurality of packages 503. The lid frame 108 may be located vertically over the plurality of packages 503.

FIG. 5B illustrates an example of a plan view of the device 500. The device 500 that includes a plurality of packages 503, a lid frame 108, a thermal interface material (TIM) 106 and the adhesive 107. Each package from the plurality of packages 503 may include an integrated device 104 and a plurality of integrated devices 105, and an encapsulation layer 140. The thermal interface material (TIM) 106 may touch and may be located vertically over (i) a top portion and/or a top surface of the integrated device 104, and (ii) a top portion and/or a top surface of the plurality of integrated devices 105. The adhesive 107 may touch and may be located vertically over the encapsulation layer 140. The adhesive 107 may laterally surrounds the thermal interface material (TIM) 106 coupled to and touching the integrated device 104 and the plurality of integrated devices 105.

A metallization portion (e.g., 320, 340, 420, 440) may include a redistribution portion. A plurality of metallization interconnects (e.g., 323, 343, 423, 443) may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect). The above description of a metallization portion may apply to other metallization portions described in the disclosure.

An integrated device (e.g., 303, 305) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 300) may be implemented in a radio frequency (RF) package. The RF package may be a radio frequency front end (RFFE) package. A package (e.g., 300) may be configured to provide Wireless Fidelity (WiFi) communication and/or cellular communication (e.g., 2G, 3G, 4G, 5G). The packages (e.g., 300) may be configured to support Global System for Mobile (GSM) Communications, Universal Mobile Telecommunications System (UMTS), and/or Long-Term Evolution (LTE). The packages may be configured to transmit and receive signals having different frequencies and/or communication protocols.

### Exemplary Sequence for Fabricating a Package Comprising a Passive Device

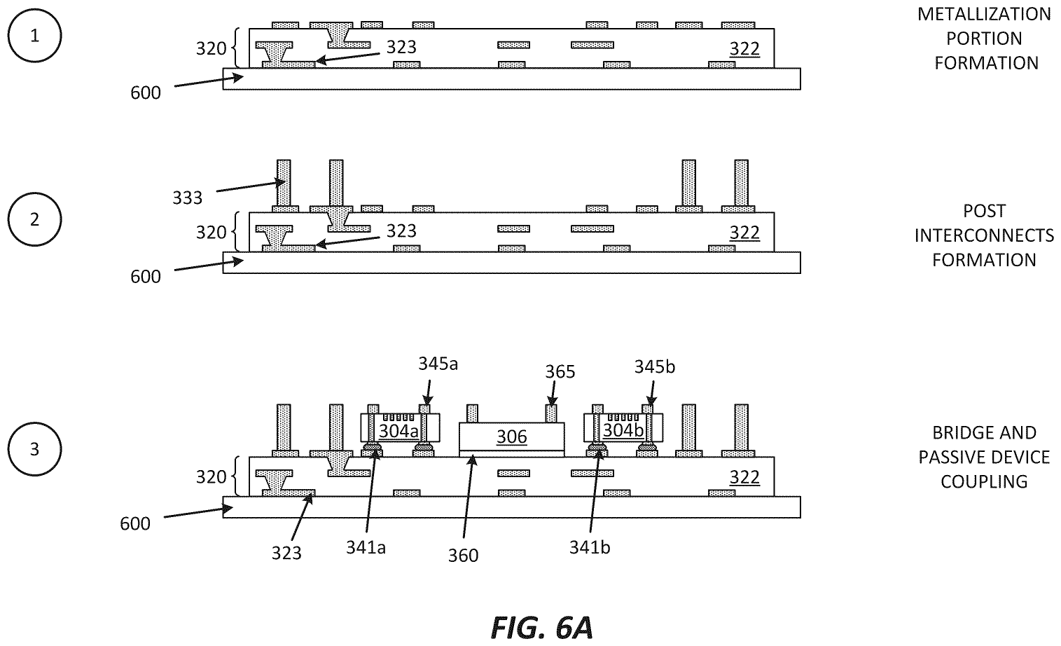

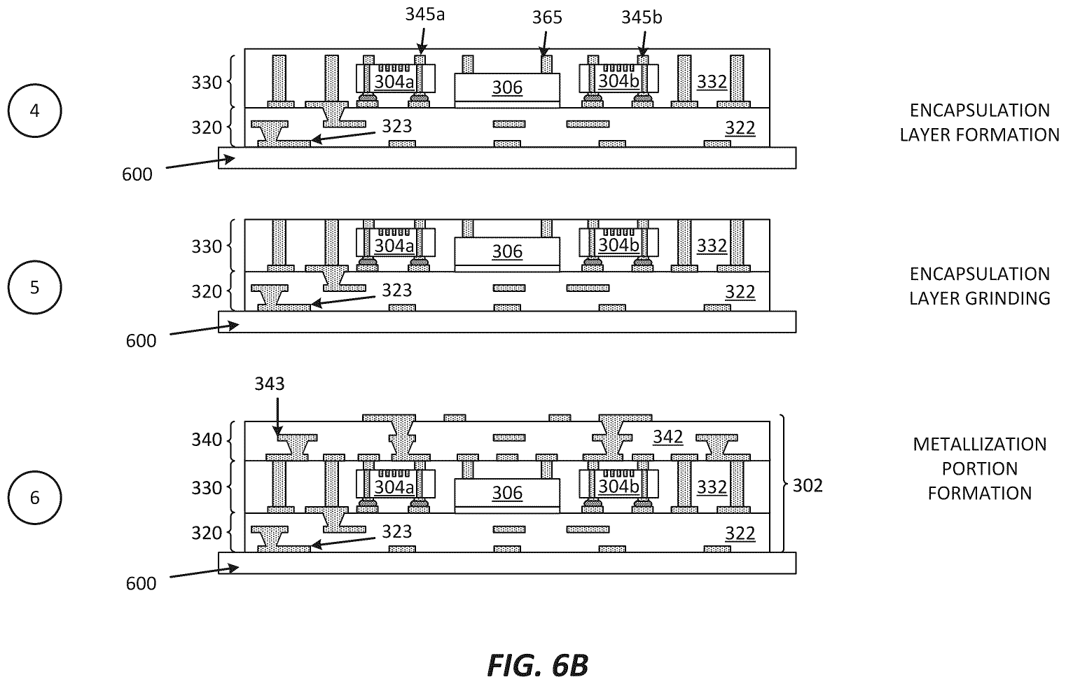

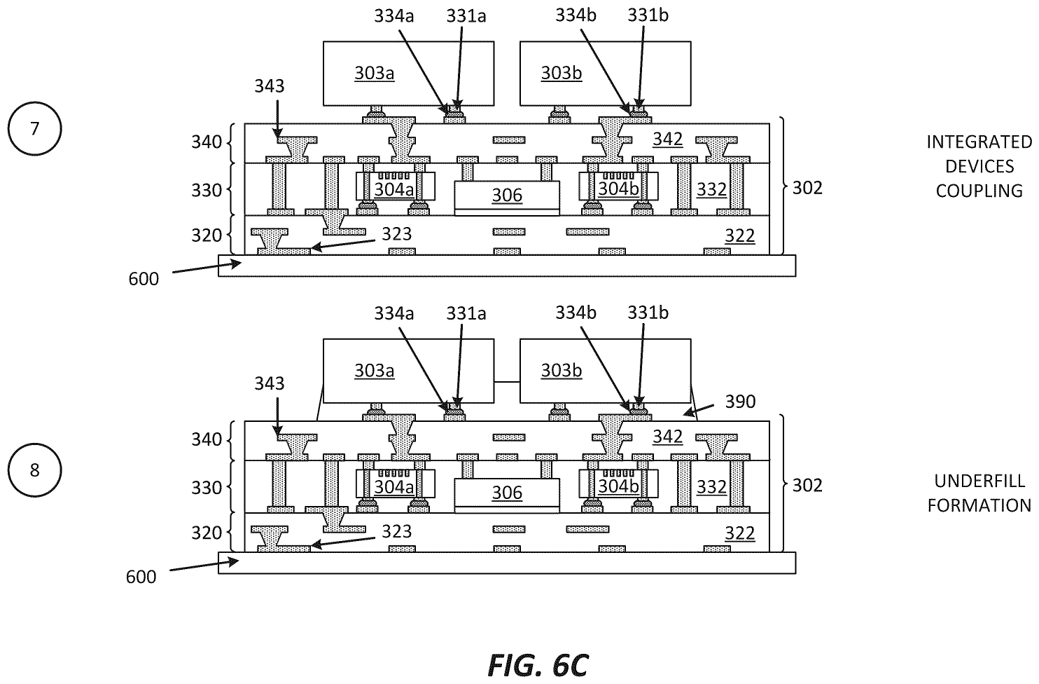

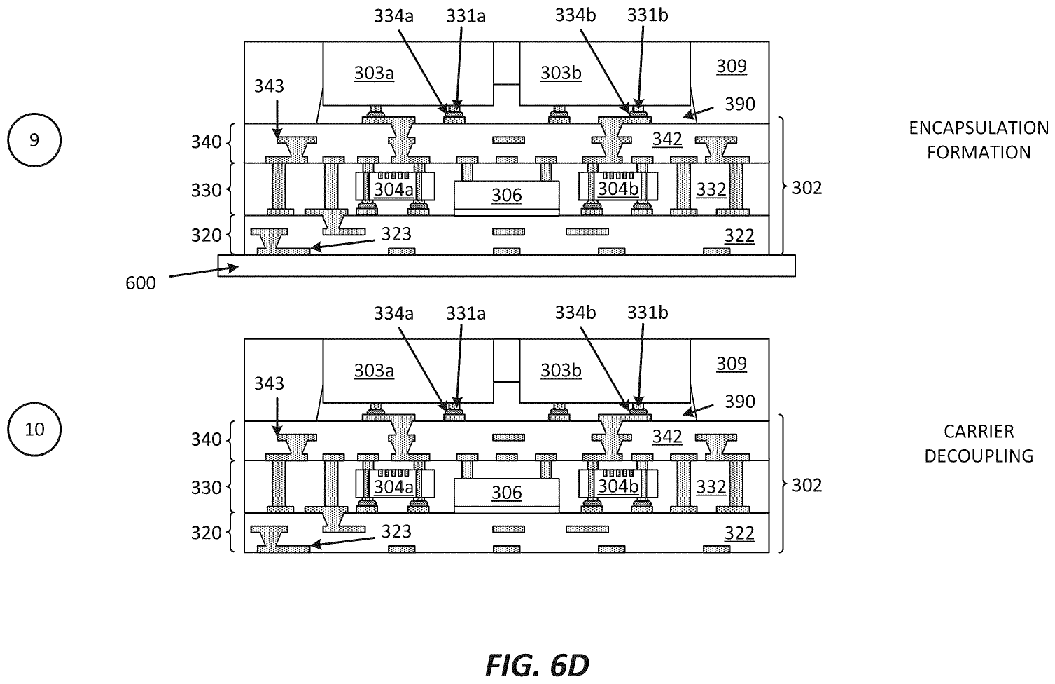

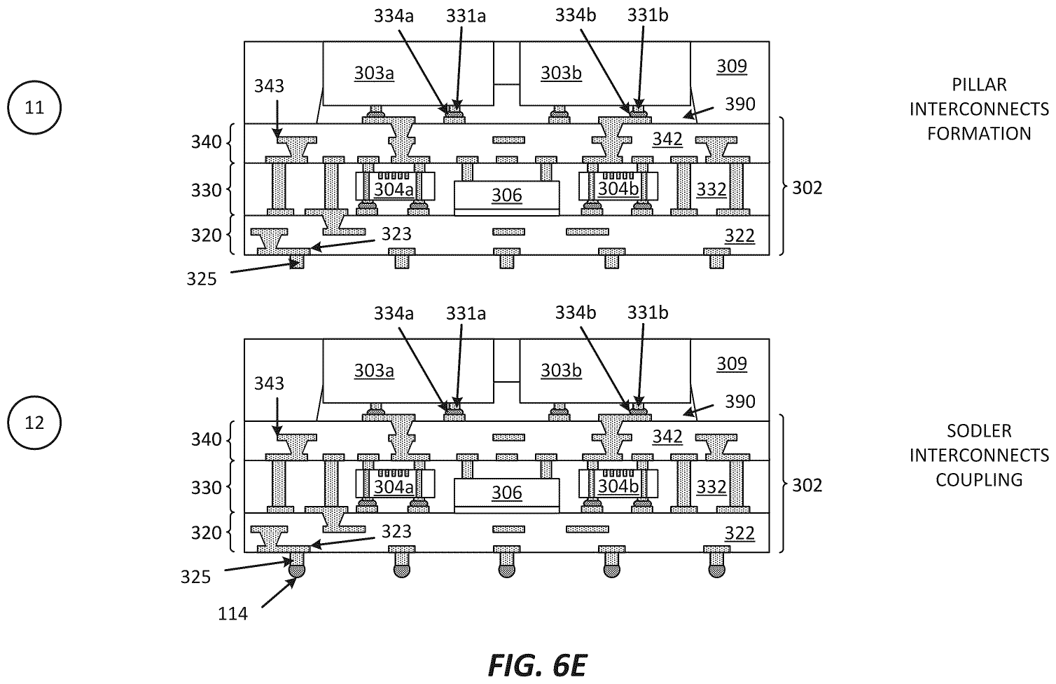

In some implementations, fabricating a package includes several processes. FIGS. 6A-6E illustrate an exemplary sequence for providing or fabricating a package. In some implementations, the sequence of FIGS. 6A-6E may be used to provide or fabricate the package 300. However, the process of FIGS. 6A-6E may be used to fabricate any of the packages described in the disclosure.

It should be noted that the sequence of FIGS. 6A-6E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

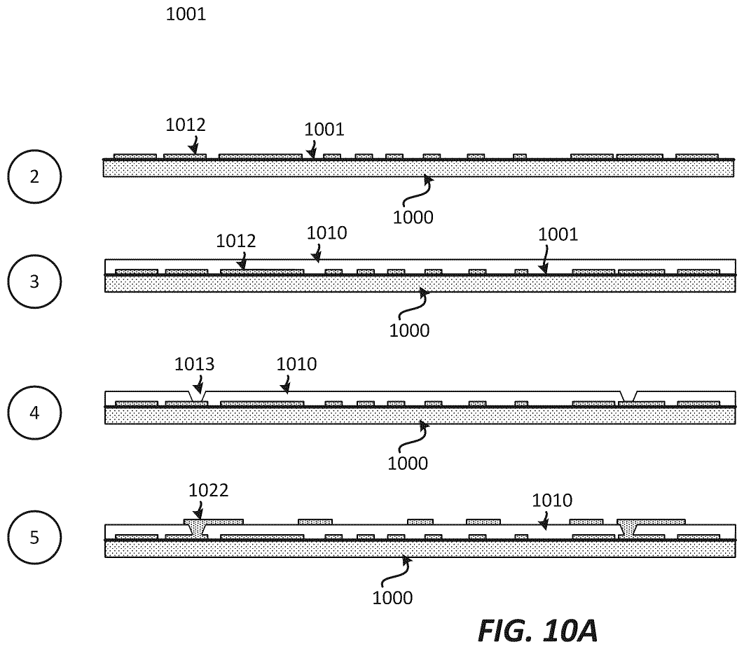

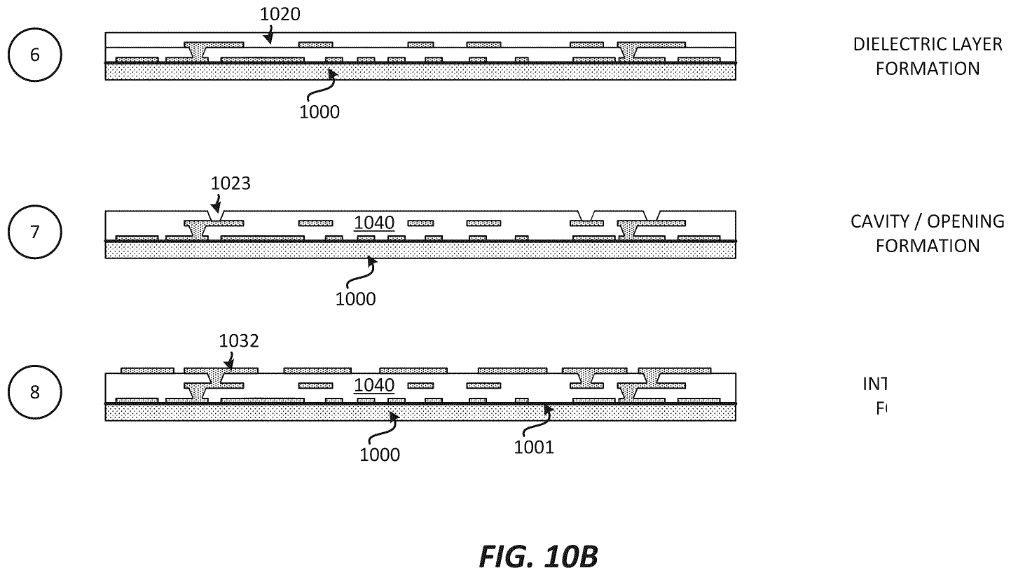

Stage 1 of FIG. 6A, illustrates a state after a carrier 600 and a metallization portion 320 is formed on the carrier 600. The carrier 600 may include a glass carrier. The metallization portion 320 includes at least one dielectric layer 322 and a plurality of metallization interconnects 323. In some implementations, the metallization portion 320 may be a first metallization portion. In some implementations, the at least one dielectric layer 322 may be an at least first dielectric layer. In some implementations, the plurality of metallization interconnects 323 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 320 comprising the at least one dielectric layer 322 and the plurality of metallization interconnects 323. An example of forming a metallization portion is illustrated and described below in at least FIGS. 10A-10B.

Stage 2 of FIG. 6A, illustrates a state after a plurality of post interconnects 333 are formed and coupled to the metallization portion 320. The plurality of post interconnects 333 may be coupled to the plurality of metallization interconnects 323. A lithography process, a plating process, a strip process and/or an etching process may be used to form the plurality of post interconnects 333. In some implementations, the metallization portion 320 may be optional. In such instances, the plurality of post interconnects 333 may be formed and coupled to the carrier 600.

Stage 3 of FIG. 6A, illustrates a state after a bridge 306 is coupled to the metallization portion 320. A back side of the bridge 306 is coupled to the metallization portion 320 through an adhesive 360. The bridge 306 may include the plurality of post interconnects 365. The back side of a bridge (e.g., silicon bridge) may be a side that includes a bridge substrate (e.g., silicon bridge substrate). The front side of a bridge may be a side that includes a bridge interconnect and/or a bridge dielectric layer.

Stage 3 of FIG. 6A, also illustrates a state after a passive device 304a and a passive device 304b are coupled to the metallization portion 320. A back side of the passive device 304a may be coupled to metallization portion 320 through a plurality of solder interconnects 341a. A back side of the passive device 304b may be coupled to metallization portion 320 through a plurality of solder interconnects 341b. The passive device 304a may include the plurality of post interconnects 345a. The passive device 304b may include the plurality of post interconnects 345b. A solder reflow process may be used to couple the passive device 304a and/or the passive device 304b to the metallization portion 320.

Stage 4 of FIG. 6B, illustrates a state after an encapsulation layer 332 is formed and coupled to the metallization portion 320. The encapsulation layer 332 may be a first encapsulation layer. The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. The encapsulation layer 332 may at least partially encapsulate the plurality of post interconnects 333, the bridge 306 the passive device 304a and/or the passive device 304b, the plurality of post interconnects 365, the plurality of post interconnects 345a and/or the plurality of post interconnects 345b. The encapsulation layer 332 may be over molded and grinded

Stage 5 of FIG. 6B, illustrates a state a portion of the encapsulation layer 332 is removed. The encapsulation layer 332 may be grinded to form an encapsulation layer 332 with a planar surface. Portions of the plurality of post interconnects 333 and/or other post interconnects (e.g., 345a, 345b, 365) may also be removed. Stage 5 of FIG. 6B, may illustrate the encapsulated portion 330 that is coupled to the metallization portion 320.

Stage 6 of FIG. 6B, illustrates a state after a metallization portion 340 is formed over and coupled to the encapsulated portion 330. The metallization portion 340 may be formed over the encapsulation layer 332. The metallization portion 340 includes at least one dielectric layer 342 and a plurality of metallization interconnects 343. In some implementations, the metallization portion 340 may be a second metallization portion. In some implementations, the at least one dielectric layer 342 may be an at least second dielectric layer. In some implementations, the plurality of metallization interconnects 343 may be a second plurality of metallization interconnects. The plurality of metallization interconnects 343 may be coupled to the plurality of post interconnects 333 and/or other post interconnects (e.g., 345a, 345b, 365) in the encapsulation layer 332. In some implementations, a deposition process, a lamination process, an etching process (e.g., photo etching process), a laser process, an exposure process, a development process, a lithography process, a plating process, and/or a strip process may be used to form the metallization portion 340 comprising the at least one dielectric layer 342 and the plurality of metallization interconnects 343. An example of forming a metallization portion is illustrated and described below in at least FIGS. 10A-10B. Stage 6 may illustrate a package interposer 302 that includes the metallization portion 320, the encapsulated portion 330 and the metallization portion 340. The encapsulated portion 330 may be located between the metallization portion 320 and the metallization portion 340.

Stage 7 of FIG. 6C, illustrates a state after integrated devices are coupled to the package interposer 302. The integrated device 303a is coupled to the metallization portion 340 through a plurality of pillar interconnects 331a and a plurality of solder interconnects 334a. A solder reflow process may be used to couple the integrated device 303a to the metallization portion 340. The integrated device 303b is coupled to the metallization portion 340 through a plurality of pillar interconnects 331b and a plurality of solder interconnects 334b. A solder reflow process may be used to couple the integrated device 303b to the metallization portion 340.

Stage 8 of FIG. 6C, illustrates a state after an underfill 390 is provided. The underfill 390 may be disposed on the package interposer 302. The underfill 390 may be located between (i) the metallization portion 340 and (ii) the integrated device 303a and/or the integrated device 303b. In some implementations, the underfill 390 may include a composite material comprising an epoxy polymer with filler.

Stage 9 of FIG. 6D, illustrates a state after an encapsulation layer 309 is formed and coupled to the package interposer 302. The encapsulation layer 309 is coupled to the metallization portion 340. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may include a different material and/or a different composition from the underfill 390. The encapsulation layer 309 may be over molded and a grinding process may be used to remove a portion of the encapsulation layer 309. The encapsulation layer 309 may at least partially encapsulate the integrated device 303a and/or the integrated device 303b.

Stage 10 of FIG. 6D, illustrates a state after the package interposer 302 is decoupled from the carrier 600. The package interposer 302 may be detached from the carrier 600.

Stage 11 of FIG. 6E, illustrates a state after a plurality of pillar interconnects 325 are formed and coupled to the metallization portion 320. The plurality of pillar interconnects 325 may be coupled to the plurality of metallization interconnects 323. A lithography process, a plating process, a strip process and/or an etching process may be used to form the plurality of pillar interconnects 325. The plurality of pillar interconnects 325 may be optional.

Stage 12 of FIG. 6E, illustrates a state after a plurality of solder interconnects 114 are coupled to the plurality of pillar interconnects 325. A solder reflow process may be used to couple the plurality of pillar interconnects 325. In some implementations, the plurality of solder interconnects 318 may be coupled to the plurality of metallization interconnects 323. Stage 12 of FIG. 6E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

Once the package and/or integrated devices are fabricated and/or assembled, the package and/or integrated devices may be coupled to a substrate or a board, and a lid frame may be coupled to the substrate and/or board.

### Exemplary Flow Diagram of a Method for Fabricating a Package Comprising a Passive Device

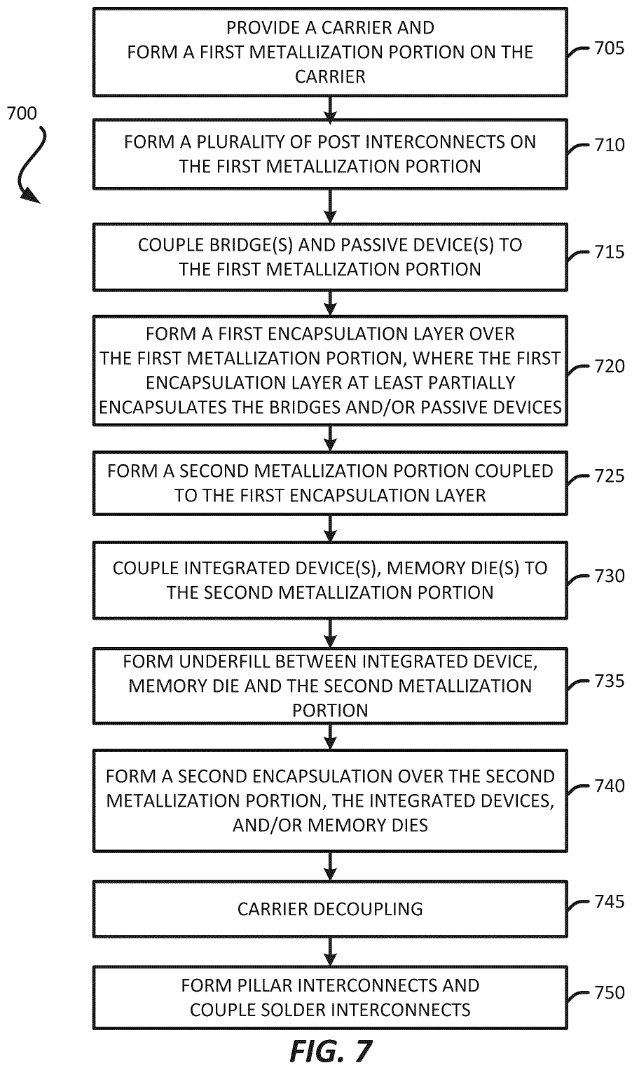

In some implementations, fabricating a package includes several processes. FIG. 7 illustrates an exemplary flow diagram of a method 700 for providing or fabricating a package. In some implementations, the method 700 of FIG. 7 may be used to provide or fabricate the package 300 described in the disclosure. However, the method 700 may be used to provide or fabricate any of the packages described in the disclosure.

It should be noted that the method 700 of FIG. 7 may combine one or more processes in order to simplify and/or clarify the method for providing or fabricating a package. In some implementations, the order of the processes may be changed or modified.

The method provides (at 705) a carrier and forms a first metallization portion on the carrier. Stage 1 of FIG. 6A, illustrates and describes an example of a state after a carrier 600 and a metallization portion 320 is formed on the carrier 600. The carrier 600 may include a glass carrier. The metallization portion 320 includes at least one dielectric layer 322 and a plurality of metallization interconnects 323. In some implementations, the metallization portion 320 may be a first metallization portion. In some implementations, the at least one dielectric layer 322 may be an at least first dielectric layer. In some implementations, the plurality of metallization interconnects 323 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 320 comprising the at least one dielectric layer 322 and the plurality of metallization interconnects 323. An example of forming a metallization portion is illustrated and described below in at least FIGS. 10A-10B.

The method forms (at 710) a plurality of post interconnects on the first metallization portion. Stage 2 of FIG. 6A, illustrates and describes an example of a state after a plurality of post interconnects 333 are formed and coupled to the metallization portion 320. The plurality of post interconnects 333 may be coupled to the plurality of metallization interconnects 323. A lithography process, a plating process, a strip process and/or an etching process may be used to form the plurality of post interconnects 333. In some implementations, the metallization portion 320 may be optional. In such instances, the plurality of post interconnects 333 may be formed and coupled to the carrier 600.

The method couples (at 715) at least one bridge and/or at least passive device to the first metallization portion. Stage 3 of FIG. 6A, illustrates and describes an example of a state after a bridge 306 is coupled to the metallization portion 320. A back side of the bridge 306 is coupled to the metallization portion 320 through an adhesive 360. The bridge 306 may include the plurality of post interconnects 365. The back side of a bridge (e.g., silicon bridge) may be a side that includes a bridge substrate (e.g., silicon bridge substrate). The front side of a bridge may be a side that includes a bridge interconnect and/or a bridge dielectric layer. Stage 3 of FIG. 6A, also illustrates and describes an example of a state after a passive device 304a and a passive device 304b are coupled to the metallization portion 320. A back side of the passive device 304a may be coupled to metallization portion 320 through a plurality of solder interconnects 341a. A back side of the passive device 304b may be coupled to metallization portion 320 through a plurality of solder interconnects 341b. The passive device 304a may include the plurality of post interconnects 345a. The passive device 304b may include the plurality of post interconnects 345b. A solder reflow process may be used to couple the passive device 304a and/or the passive device 304b to the metallization portion 320.

The method forms (at 720) a first encapsulation layer over the first metallization portion. Stage 4 of FIG. 6B, illustrates and describes an example of a state after an encapsulation layer 332 is formed and coupled to the metallization portion 320. The encapsulation layer 332 may be a first encapsulation layer. The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. The encapsulation layer 332 may at least partially encapsulate the plurality of post interconnects 333, the bridge 306 the passive device 304a and/or the passive device 304b, the plurality of post interconnects 365, the plurality of post interconnects 345a and/or the plurality of post interconnects 345b. The encapsulation layer 332 may be over molded. Forming the first encapsulation layer may include removing portions of the first encapsulation layer. Stage 5 of FIG. 6B, illustrates and describes an example of a state a portion of the encapsulation layer 332 is removed. The encapsulation layer 332 may be grinded to form an encapsulation layer 332 with a planar surface. Portions of the plurality of post interconnects 333 and/or other post interconnects may also be removed. Stage 5 of FIG. 6B, may illustrate the encapsulated portion 330 that is coupled to the metallization portion 320.

The method forms (at 725) a second metallization over the encapsulated portion. Stage 6 of FIG. 6B, illustrates and describes an example of a state after a metallization portion 340 is formed over and coupled to the encapsulated portion 330. The metallization portion 340 may be formed over the encapsulation layer 332. The metallization portion 340 includes at least one dielectric layer 342 and a plurality of metallization interconnects 343. In some implementations, the metallization portion 340 may be a second metallization portion. In some implementations, the at least one dielectric layer 342 may be an at least second dielectric layer. In some implementations, the plurality of metallization interconnects 343 may be a second plurality of metallization interconnects. The plurality of metallization interconnects 343 may be coupled to the plurality of post interconnects 333 and/or other post interconnects in the encapsulation layer 332. In some implementations, a deposition process, a lamination process, an etching process (e.g., photo etching process), a laser process, an exposure process, a development process, a lithography process, a plating process, and/or a strip process may be used to form the metallization portion 340 comprising the at least one dielectric layer 342 and the plurality of metallization interconnects 343. An example of forming a metallization portion is illustrated and described below in at least FIGS. 10A-10B. Stage 6 may illustrate a package interposer 302 that includes the metallization portion 320, the encapsulated portion 330 and the metallization portion 340. The encapsulated portion 330 may be located between the metallization portion 320 and the metallization portion 340.

The method places and couples (at 730) integrated devices and/or memory dies to the second metallization portion. Stage 7 of FIG. 6C, illustrates and describes an example of a state after integrated devices are coupled to the package interposer 302. The integrated device 303a is coupled to the metallization portion 340 through a plurality of pillar interconnects 331a and a plurality of solder interconnects 334a. A solder reflow process may be used to couple the integrated device 303a to the metallization portion 340. The integrated device 303b is coupled to the metallization portion 340 through a plurality of pillar interconnects 331b and a plurality of solder interconnects 334b. A solder reflow process may be used to couple the integrated device 303b to the metallization portion 340.

The method provides and forms (at 735) an underfill. Stage 8 of FIG. 6C, illustrates and describes an example of a state after an underfill 390 is provided. The underfill 390 may be disposed on the package interposer 302. The underfill 390 may be located between (i) the metallization portion 340 and (ii) the integrated device 303a and/or the integrated device 303b. In some implementations, the underfill 390 may include a composite material comprising an epoxy polymer with filler.

The method forms (at 740) a second encapsulation layer. Stage 9 of FIG. 6D, illustrates and describes an example of a state after an encapsulation layer 309 is formed and coupled to the package interposer 302. The encapsulation layer 309 is coupled to the metallization portion 340. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may include a different material and/or a different composition from the underfill 390. The encapsulation layer 309 may be over molded and a grinding process may be used to remove a portion of the encapsulation layer 309. The encapsulation layer 309 may at least partially encapsulate the integrated device 303a and/or the integrated device 303b.

The method decouples (at 745) the carrier. Stage 10 of FIG. 6D, illustrates and describes an example of a state after the package interposer 302 is decoupled from the carrier 600. The package interposer 302 may be detached from the carrier 600.

The method forms (at 750) a plurality of pillar interconnects and solder interconnects. Stage 11 of FIG. 6E, illustrates and describes an example of a state after a plurality of pillar interconnects 325 are formed and coupled to the metallization portion 320. The plurality of pillar interconnects 325 may be coupled to the plurality of metallization interconnects 323. A lithography process, a plating process, a strip process and/or an etching process may be used to form the plurality of pillar interconnects 325. The plurality of pillar interconnects 325 may be optional.

Stage 12 of FIG. 6E, illustrates and describes an example of a state after a plurality of solder interconnects 114 are coupled to the plurality of pillar interconnects 325. A solder reflow process may be used to couple the plurality of pillar interconnects 325. In some implementations, the plurality of solder interconnects 318 may be coupled to the plurality of metallization interconnects 323. Stage 12 of FIG. 6E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

Once the package and/or integrated devices are fabricated and/or assembled, the package and/or integrated devices may be coupled to a substrate or a board, and a lid frame may be coupled to the substrate and/or board.

### Exemplary Sequence for Fabricating a Package Comprising a Passive Device

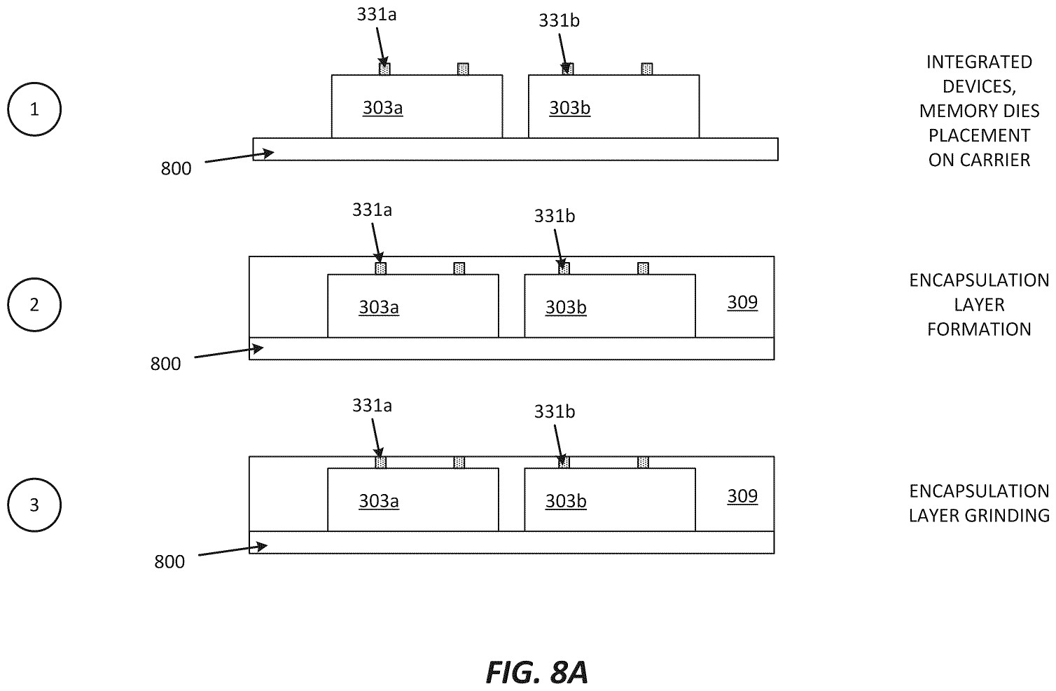

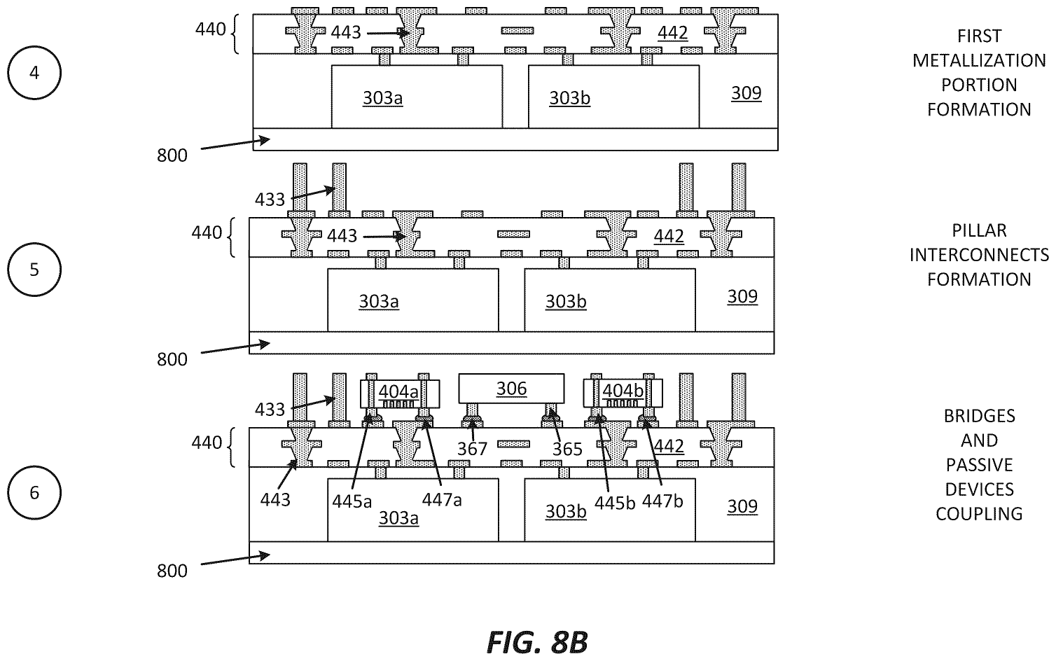

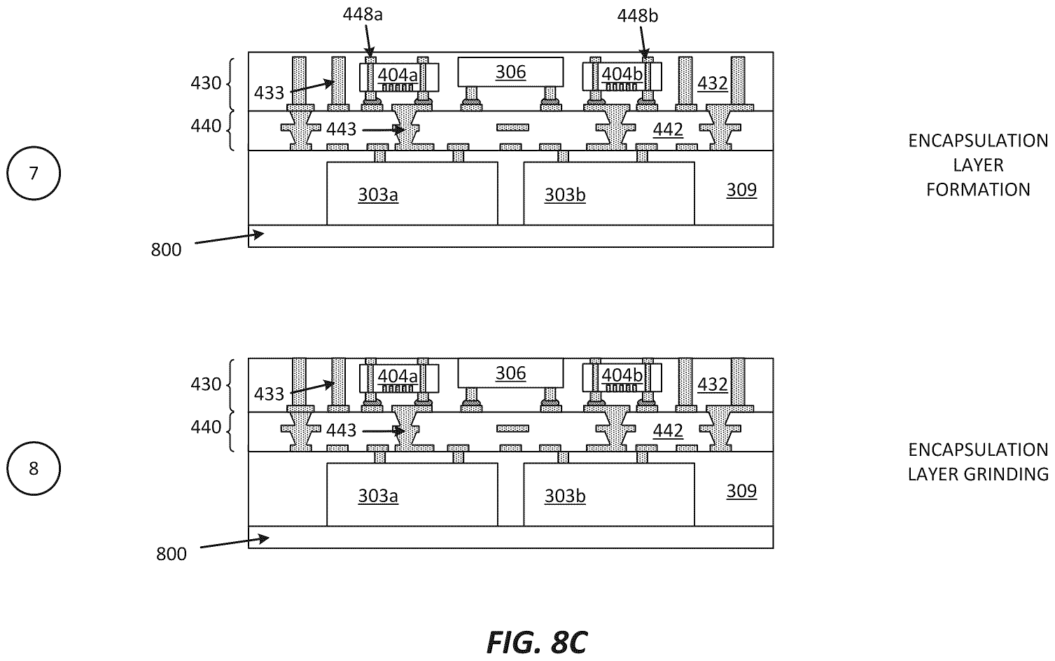

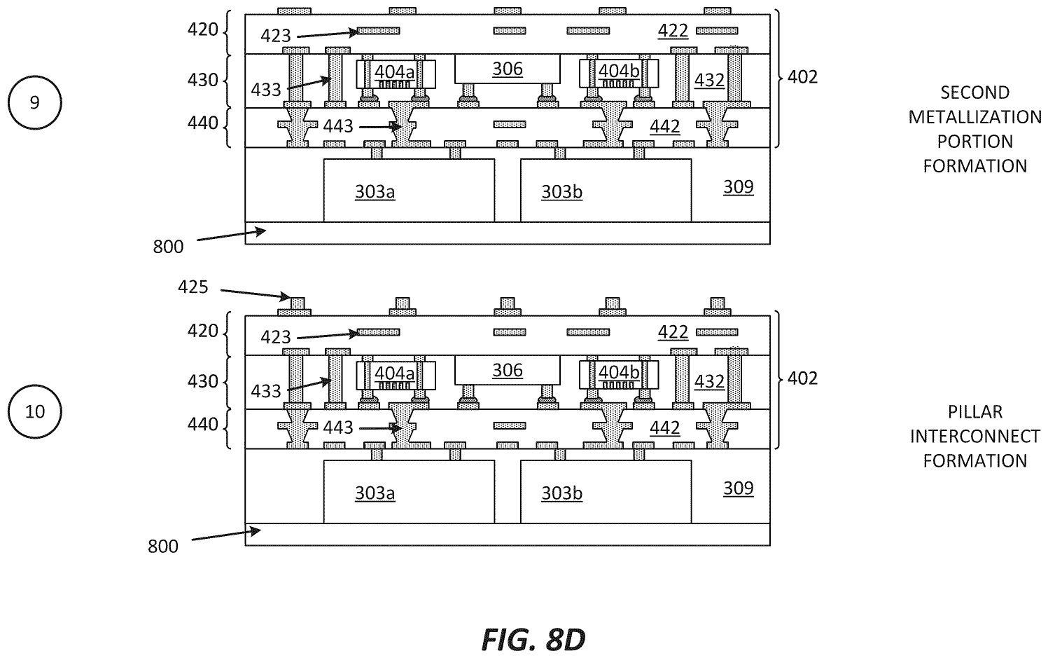

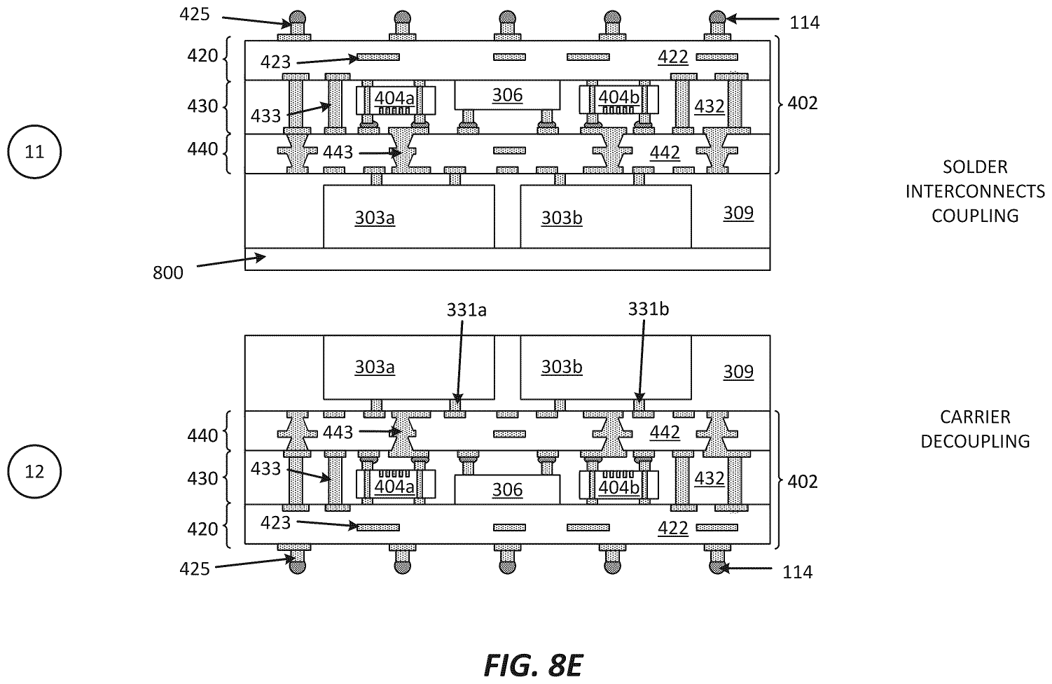

In some implementations, fabricating a package includes several processes. FIGS. 8A-8E illustrate an exemplary sequence for providing or fabricating a package. In some implementations, the sequence of FIGS. 8A-8E may be used to provide or fabricate the package 400. However, the process of FIGS. 8A-8E may be used to fabricate any of the packages described in the disclosure.

It should be noted that the sequence of FIGS. 8A-8E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 8A, illustrates a state after a carrier 800 and a plurality of integrated devices is placed on the carrier 800. The plurality of integrated devices may be coupled to the carrier 800 through one or more adhesives. A back side of the integrated device 303a is placed and/or coupled to the carrier 800. The integrated device 303a may include a plurality of pillar interconnects 331a. A back side of the integrated device 303b is placed and/or coupled to the carrier 800. The integrated device 303b may include a plurality of pillar interconnects 331b.

Stage 2 of FIG. 8A, illustrates a state after an encapsulation layer 309 is formed and coupled to the carrier 800, the integrated device 303a, and the integrated device 303b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded. The encapsulation layer 309 may at least partially encapsulate the integrated device 303a, the integrated device 303b, the plurality of pillar interconnects 331a and/or the plurality of pillar interconnects 331b.

Stage 3 of FIG. 8A, illustrates a state after portions of the encapsulation layer 309 are removed. A grinding process may be used remove portions of the encapsulation layer 309. In some implementations, portions of pillar interconnects (e.g., 331a, 331b) and/or part of the integrated device 303a and/or the integrated device 303b may also be removed.

Stage 4 of FIG. 8B, illustrates a state after a metallization portion 440 is formed and coupled to the encapsulation layer 309. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 440 comprising the at least one dielectric layer 442 and the plurality of metallization interconnects 443. An example of forming a metallization portion is illustrated and described below in at least FIGS. 10A-10B.

Stage 5 of FIG. 8B, illustrates a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

Stage 6 of FIG. 8B, illustrates a state after a bridge 306 is coupled to the metallization portion 440. A front side of the bridge 306 is coupled to the metallization portion 440 through a plurality of post interconnects 365 and/or a plurality of solder interconnects 367. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer. A solder reflow process may be used to couple the bridge 306 to the metallization portion 440.

Stage 6 of FIG. 8B, also illustrates a state after a passive device 404a and a passive device 404b are coupled to the metallization portion 440. A front side of the passive device 404a may be coupled to metallization portion 440 through a plurality of post interconnects 445a and/or a plurality of solder interconnects 447a. A front side of the passive device 404b may be coupled to metallization portion 440 through a plurality of post interconnects 445b and/or a plurality of solder interconnects 447b. A solder reflow process may be used to couple the passive device 404a and/or the passive device 404b to the metallization portion 440.

Stage 7 of FIG. 8C, illustrates a state after an encapsulation layer 432 is formed and coupled to the metallization portion 440. The encapsulation layer 432 may be a second encapsulation layer. The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the bridge 306, the passive device 404a and/or the passive device 404b. The encapsulation layer 432 may be over molded. The encapsulation layer 432 may at least partially encapsulate the plurality of post interconnects 365, the plurality of interconnects 448a (e.g., post interconnects), the plurality of interconnects 448b (e.g., post interconnects), the plurality of solder interconnects 367, the plurality of solder interconnects 447a and/or, the plurality of solder interconnects 447b.

Stage 8 of FIG. 8C, illustrates a state a portion of the encapsulation layer 432 is removed. The encapsulation layer 432 may be grinded to form an encapsulation layer 432 with a planar surface. Portions of the plurality of post interconnects 433 and/or other post interconnects (e.g., 448a, 448b) may also be removed. Stage 8 may illustrate an encapsulated portion 430 that includes an encapsulation layer 432, a plurality of post interconnects 433, at least one bridge and at least one passive device. Stage 8 of FIG. 8C, illustrates an encapsulated portion 430 that is coupled to the metallization portion 440.

Stage 9 of FIG. 8D, illustrates a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The plurality of metallization interconnects 423 may be coupled to and touch, the plurality of post interconnects 433 and/or other post interconnects (e.g., 448a, 448b) in the encapsulation layer 432. In some implementations, a deposition process, a lamination process, an etching process (e.g., photo etching process), a laser process, an exposure process, a development process, a lithography process, a plating process, and/or a strip process may be used to form the metallization portion 420 comprising the at least one dielectric layer 422 and the plurality of metallization interconnects 423. Stage 9 may illustrate a package interposer 402 that includes the metallization portion 420, the encapsulated portion 430 and the metallization portion 440. The encapsulated portion 430 may be located between the metallization portion 420 and the metallization portion 440. An example of forming a metallization portion is illustrated and described below in at least FIGS. 10A-10B.

Stage 10 of FIG. 8D, illustrates a state after a plurality of pillar interconnects 425 are formed and coupled to the metallization portion 420. The plurality of pillar interconnects 425 may be coupled to the plurality of metallization interconnects 423. A lithography process, a plating process, a strip process and/or an etching process may be used to form the plurality of pillar interconnects 425. The plurality of pillar interconnects 425 may be optional. In some implementations, the metallization portion 420 may be optional. In such instances, the plurality of pillar interconnects 425 may be formed and coupled to the plurality of post interconnects 433.

Stage 11 of FIG. 8E, illustrates a state after a plurality of solder interconnects 114 are coupled to the plurality of pillar interconnects 425. A solder reflow process may be used to couple the plurality of pillar interconnects 425. In some implementations, the plurality of solder interconnects 114 may be coupled to the plurality of metallization interconnects 423.

Stage 12 of FIG. 8E, illustrates a state after the package interposer 402 is decoupled from the carrier 800. The package interposer 402 may be detached from the carrier 800. Stage 12 of FIG. 8E may illustrate a package 400.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Passive Device

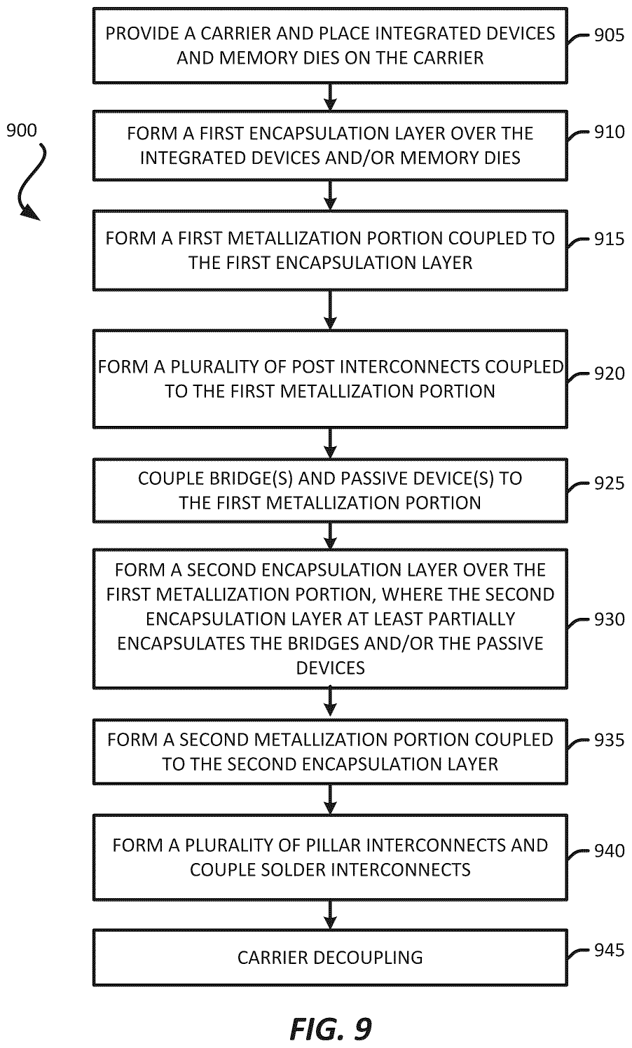

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 400 described in the disclosure. However, the method 900 may be used to provide or fabricate any of the packages described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a carrier and places (at 905) integrated devices on the carrier. Stage 1 of FIG. 8A, illustrates and describes an example of a state after a carrier 800 and a plurality of integrated devices is placed on the carrier 800. The plurality of integrated devices may be coupled to the carrier 800 through one or more adhesives. A back side of the integrated device 303a is placed and/or coupled to the carrier 800. The integrated device 303a may include a plurality of pillar interconnects 331a. A back side of the integrated device 303b is placed and/or coupled to the carrier 800. The integrated device 303b may include a plurality of pillar interconnects 331b.

The method forms (at 910) a first encapsulation layer over the integrated devices and/or the memory dies. Stage 2 of FIG. 8A, illustrates and describes an example of a state after an encapsulation layer 309 is formed and coupled to the carrier 800, the integrated device 303a, and the integrated device 303b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded. The encapsulation layer 309 may at least partially encapsulate the integrated device 303a, the integrated device 303b, the plurality of pillar interconnects 331a and/or the plurality of pillar interconnects 331b. Forming an encapsulation layer may include removing portions of the encapsulation layer. Stage 3 of FIG. 8A, illustrates and describes an example of a state after portions of the encapsulation layer 309 are removed. A grinding process may be used remove portions of the encapsulation layer 309. In some implementations, portions of pillar interconnects (e.g., 331a, 331b) and/or part of the integrated device 303a and/or the integrated device 303b may also be removed.

The method forms (at 915) a first metallization portion coupled to the encapsulation layer. Stage 4 of FIG. 8B, illustrates and describes an example of a state after a metallization portion 440 is formed and coupled to the encapsulation layer 309. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 440 comprising the at least one dielectric layer 442 and the plurality of metallization interconnects 443. An example of forming a metallization portion is illustrated and described below in at least FIGS. 10A-10B.

The method forms (at 920) a plurality of post interconnects that are coupled to the first metallization portion. Stage 5 of FIG. 8B, illustrates and describes an example of a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

The method couples (at 925) a bridge and passive devices to the first metallization portion. Stage 6 of FIG. 8B, illustrates and describes an example of a state after a bridge 306 is coupled to the metallization portion 440. A front side of the bridge 306 is coupled to the metallization portion 440 through a plurality of post interconnects 365 and/or a plurality of solder interconnects 367. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer. A solder reflow process may be used to couple the bridge 306 to the metallization portion 440.

Stage 6 of FIG. 8B, also illustrates and describes an example of a state after a passive device 404a and a passive device 404b are coupled to the metallization portion 440. A front side of the passive device 404a may be coupled to metallization portion 440 through a plurality of post interconnects 445a and/or a plurality of solder interconnects 447a. A front side of the passive device 404b may be coupled to metallization portion 440 through a plurality of post interconnects 445b and/or a plurality of solder interconnects 447b. A solder reflow process may be used to couple the passive device 404a and/or the passive device 404b to the metallization portion 440.

The method forms (at 930) a second encapsulation layer over the first metallization portion. Stage 7 of FIG. 8C, illustrates and describes an example of a state after an encapsulation layer 432 is formed and coupled to the metallization portion 440. The encapsulation layer 432 may be a second encapsulation layer. The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the bridge 306, the passive device 404a and/or the passive device 404b. The encapsulation layer 432 may be over molded. The encapsulation layer 432 may at least partially encapsulate the plurality of post interconnects 365, the plurality of interconnects 448a (e.g., post interconnects), the plurality of interconnects 448b (e.g., post interconnects), the plurality of solder interconnects 367, the plurality of solder interconnects 447a and/or, the plurality of solder interconnects 447b. Forming the encapsulation layer may include removing portions of an encapsulation layer. Stage 8 of FIG. 8C, illustrates and describes an example of a state a portion of the encapsulation layer 432 is removed. The encapsulation layer 432 may be grinded to form an encapsulation layer 432 with a planar surface. Portions of the plurality of post interconnects 433 and/or other post interconnects (e.g., 448a, 448b) may also be removed. Stage 8 may illustrate an encapsulated portion 430 that includes an encapsulation layer 432, a plurality of post interconnects 433, at least one bridge and at least one passive device. Stage 8 of FIG. 8C, illustrates an encapsulated portion 430 that is coupled to the metallization portion 440.

The method forms (at 935) a second metallization portion that is coupled to the encapsulated portion. Stage 9 of FIG. 8D, illustrates and describes an example of a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The plurality of metallization interconnects 423 may be coupled to and touch, the plurality of post interconnects 433 and/or other post interconnects (e.g., 448a, 448b) in the encapsulation layer 432. In some implementations, a deposition process, a lamination process, an etching process (e.g., photo etching process), a laser process, an exposure process, a development process, a lithography process, a plating process, and/or a strip process may be used to form the metallization portion 420 comprising the at least one dielectric layer 422 and the plurality of metallization interconnects 423. Stage 9 may illustrate a package interposer 402 that includes the metallization portion 420, the encapsulated portion 430 and the metallization portion 440. The encapsulated portion 430 may be located between the metallization portion 420 and the metallization portion 440. An example of forming a metallization portion is illustrated and described below in at least FIGS. 10A-10B.

The method forms (at 940) a plurality of pillar interconnects and/or a plurality of solder interconnects. Stage 10 of FIG. 8D, illustrates and describes an example of a state after a plurality of pillar interconnects 425 are formed and coupled to the metallization portion 420. The plurality of pillar interconnects 425 may be coupled to the plurality of metallization interconnects 423. A lithography process, a plating process, a strip process and/or an etching process may be used to form the plurality of pillar interconnects 425. The plurality of pillar interconnects 425 may be optional. In some implementations, the metallization portion 420 may be optional. In such instances, the plurality of pillar interconnects 425 may be formed and coupled to the plurality of post interconnects 433. Stage 11 of FIG. 8E, illustrates and describes an example of a state after a plurality of solder interconnects 114 are coupled to the plurality of pillar interconnects 425. A solder reflow process may be used to couple the plurality of pillar interconnects 425. In some implementations, the plurality of solder interconnects 114 may be coupled to the plurality of metallization interconnects 423.

The method decouples (at 945) a carrier from the package interposer. Stage 12 of FIG. 8E, illustrates and describes an example of a state after the package interposer 402 is decoupled from the carrier 800. The package interposer 402 may be detached from the carrier 800. Stage 12 of FIG. 8E may illustrate a package 400.

### Exemplary Sequence for Fabricating a Metallization Portion

In some implementations, fabricating a substrate includes several processes. FIGS. 10A-10B illustrate an exemplary sequence for providing or fabricating a metallization portion. In some implementations, the sequence of FIGS. 10A-10B may be used to provide or fabricate the metallization portion (e.g., 320, 340, 420, 440). However, the process of FIGS. 10A-10B may be used to fabricate any of the metallization portions described in the disclosure.

It should be noted that the sequence of FIGS. 10A-10B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 10A, illustrates a state after a carrier 1000 is provided. A seed layer 1001 may be located over the carrier 1000. The carrier 1000 may be replaced with other components and/or materials.

Stage 2 illustrates a state after a plurality of interconnects 1012 are formed. The interconnects 1012 may be located over the seed layer 1001. A lithography process, a plating process, a strip process and/or an etching process may be used to form the plurality of interconnects 1012. The interconnects 1012 may represent at least some of the interconnects from the plurality of metallization interconnects 123.

Stage 3 illustrates a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

Stage 4 illustrates a state after a plurality of cavities 1013 is formed in the dielectric layer 1010. The plurality of cavities 1013 may be formed using an etching process (e.g., photo etching process), a laser process, an exposure process and/or a development process.

Stage 5 illustrates a state after interconnects 1022 are formed in and over the dielectric layer 1010, including in and over the plurality of cavities 1013. For example, a via, pad and/or traces may be formed. A lithography process, a plating process, a strip process and/or an etching process may be used to form the interconnects.

Stage 6, as shown in FIG. 10B, illustrates a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

Stage 7, illustrates a state after a plurality of cavities 1023 is formed in the dielectric layer 1040. The dielectric layer 1040 may represent the dielectric layer 1010 and/or the dielectric layer 1020. The plurality of cavities 1023 may be formed using an etching process (e.g., photo etching process), a laser process, an exposure process and/or a development process.

Stage 8 illustrates a state after interconnects 1032 are formed in and over the dielectric layer 1040, including in and over the plurality of cavities 1023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

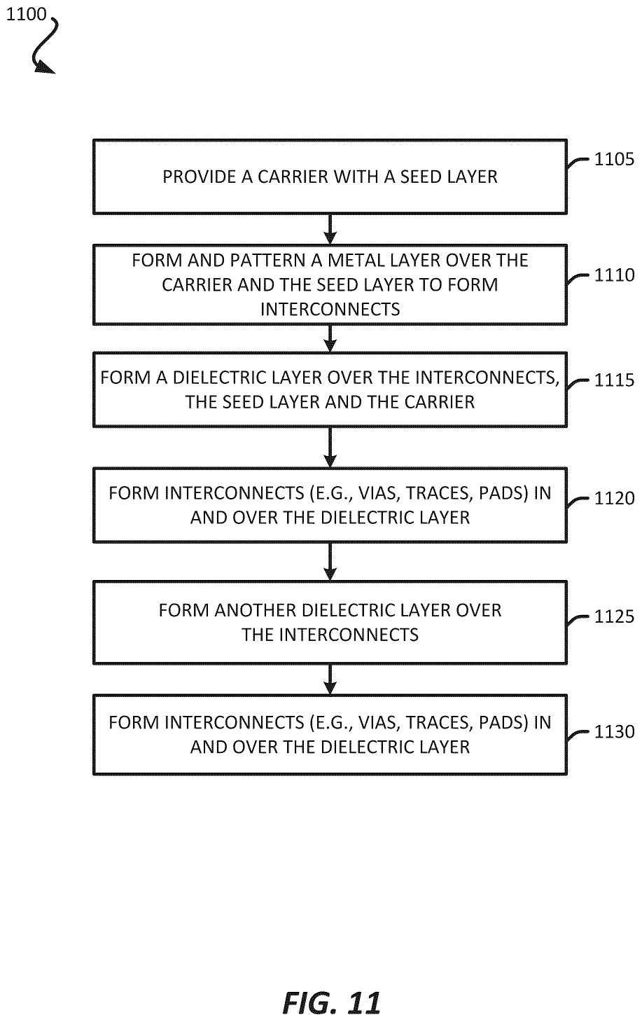

In some implementations, fabricating a substrate includes several processes. FIG. 11 illustrates an exemplary flow diagram of a method 1100 for providing or fabricating a metallization portion. In some implementations, the method 1100 of FIG. 11 may be used to provide or fabricate the metallization portion(s) of the disclosure. For example, the method 1100 of FIG. 11 may be used to fabricate the metallization portion (e.g., 320, 340, 420, 440).

It should be noted that the method 1100 of FIG. 11 may combine one or more processes in order to simplify and/or clarify the method for providing or fabricating a metallization portion. In some implementations, the order of the processes may be changed or modified.

The method provides (at 1105) a carrier with a seed layer. Stage 1 of FIG. 10A, illustrates and describes an example of a state after a carrier 1000 is provided. A seed layer 1001 may be located over the carrier 1000. The carrier 1000 may be replaced with other components and/or materials.

The method forms and patterns (at 1110) a plurality of interconnects. Stage 2 of FIG. 10A, illustrates and describes an example of a state after a plurality of interconnects 1012 are formed. The interconnects 1012 may be located over the seed layer 1001. A lithography process, a plating process, a strip process and/or an etching process may be used to form the plurality of interconnects 1012. The interconnects 1012 may represent at least some of the interconnects from the plurality of metallization interconnects 123.

The method forms (at 1110) a dielectric layer. Stage 3 of FIG. 10A, illustrates and describes an example of a state after a dielectric layer 1010 is formed over the carrier 1000, the seed layer 1001 and the plurality of interconnects 1012. A deposition and/or lamination process may be used to form the dielectric layer 1010. The dielectric layer 1010 may include prepreg and/or polyimide. The dielectric layer 1010 may include a photo-imageable dielectric. However, different implementations may use different materials for the dielectric layer.

The method forms (at 1120) a plurality of interconnects. Forming a plurality of interconnects may including forming a plurality of cavities in a dielectric layer and a performing a plating process. Stage 4 of FIG. 10A, illustrates and describes an example of a state after a plurality of cavities 1013 is formed in the dielectric layer 1010. The plurality of cavities 1013 may be formed using an etching process (e.g., photo etching process), a laser process, an exposure process and/or a development process.

Stage 5 of FIG. 10A, illustrates and describes an example of a state after interconnects 1022 are formed in and over the dielectric layer 1010, including in and over the plurality of cavities 1013. For example, a via, pad and/or traces may be formed. A lithography process, a plating process, a strip process and/or an etching process may be used to form the interconnects.

The method forms (at 1125) another dielectric layer. Stage 6 of FIG. 10B, illustrates and describes an example of a state after a dielectric layer 1020 is formed over the dielectric layer 1010 and the plurality of interconnects 1022. A deposition and/or lamination process may be used to form the dielectric layer 1020. The dielectric layer 1020 may include prepreg and/or polyimide. The dielectric layer 1020 may include a photo-imageable dielectric. However, different implementations may use different materials for the dielectric layer.

The method forms (at 1130) a plurality of interconnects. Forming a plurality of interconnects may including forming a plurality of cavities in a dielectric layer and a performing a plating process. Stage 7 of FIG. 10B, illustrates and describes an example of a state after a plurality of cavities 1023 is formed in the dielectric layer 1040. The dielectric layer 1040 may represent the dielectric layer 1010 and/or the dielectric layer 1020. The plurality of cavities 1023 may be formed using an etching process (e.g., photo etching process), a laser process, an exposure process and/or a development process.

Stage 8 of FIG. 10B, illustrates and describes an example of a state after interconnects 1032 are formed in and over the dielectric layer 1040, including in and over the plurality of cavities 1023. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

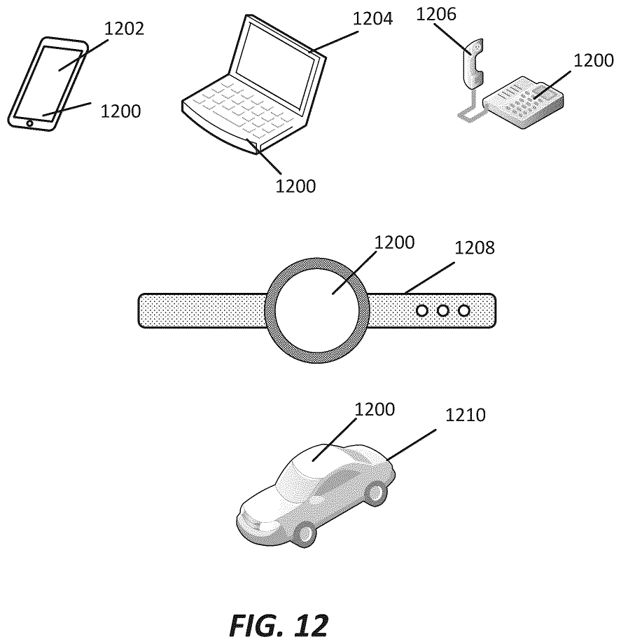

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IOT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1, 2A, 2B, 3-4, 5A-5B, 6A-6E, 7, 8A-8E, 9, 10A-10B and 11-12 may be rearranged and/or combined into a single component, process, feature or function or embodied in several components, processes, or functions. Additional elements, components, processes, and/or functions may also be added without departing from the disclosure. It should also be noted FIGS. 1, 2A, 2B, 3-4, 5A-5B, 6A-6E, 7, 8A-8E, 9, 10A-10B and 11-12 and its corresponding description in the present disclosure is not limited to dies and/or ICs. In some implementations, FIGS. 1, 2A, 2B, 3-4, 5A-5B, 6A-6E, 7, 8A-8E, 9, 10A-10B and 11-12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. A seed layer may be considered part of an interconnect. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising: a substrate; a package coupled to the substrate, the package comprising: a first integrated device; and an encapsulation layer that at least partially encapsulates the first integrated device; and a lid frame coupled to the substrate, wherein the lid frame is further coupled to the first integrated device through a thermal interface material, and wherein the lid frame is further coupled to the encapsulation layer through an adhesive.

Aspect 2: The device of aspect 1, wherein the thermal interface material touches the first integrated device and a first portion of the lid frame, and wherein the adhesive touches the encapsulation layer and a second portion of the lid frame.

Aspect 3: The device of aspect 2, wherein the adhesive laterally surrounds the thermal interface material.

Aspect 4: The device of aspects 1 through 3, wherein the lid frame is coupled to the substrate through another thermal interface material.

Aspect 5: The device of aspects 1 through 3, wherein the lid frame is coupled to the substrate through another adhesive.

Aspect 6: The device of aspects 1 through 5, wherein the package comprises a package substrate coupled to the first integrated device and the encapsulation layer.

Aspect 7: The device of aspects 1 through 6, further comprising a second integrated device coupled to the substrate, wherein the lid frame is coupled to the second integrated device through another thermal interface material.

Aspect 8: The device of aspects 1 through 6, wherein the package further comprises a second integrated device, wherein the second integrated device is at least partially encapsulated by the encapsulation layer, and wherein the lid frame is coupled to the second integrated device through another thermal interface material.

Aspect 9: The device of aspects 1 through 8, wherein the thermal interface material may touch the encapsulation layer, and wherein the adhesive may touch the first integrated device.

Aspect 10: The device of aspects 1 through 9, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IOT) device, and a device in an automotive vehicle.

Aspect 11: A device comprising: a substrate; a package coupled to the substrate, the package comprising: a package interposer comprising: a first metallization portion; a first encapsulation layer coupled to the first metallization portion; and a second metallization portion coupled to the first encapsulation layer; a first integrated device coupled to the package interposer; a second encapsulation layer that at least partially encapsulates the first integrated device; and a lid frame coupled to the substrate, wherein the lid frame is further coupled to the first integrated device through a thermal interface material, and wherein the lid frame is further coupled to the second encapsulation layer through an adhesive.

Aspect 12: The device of aspect 11, wherein the thermal interface material touches the first integrated device and a first portion of the lid frame, and wherein the adhesive touches the second encapsulation layer and a second portion of the lid frame.

Aspect 13: The device of aspect 12, wherein the adhesive laterally surrounds the thermal interface material.

Aspect 14: The device of aspects 11 through 13, wherein the lid frame is coupled to the substrate through another thermal interface material.

Aspect 15: The device of aspects 11 through 13, wherein the lid frame is coupled to the substrate through another adhesive.

Aspect 16: The device of aspects 11 through 15, wherein the package comprises a package substrate coupled to the first integrated device and the second encapsulation layer.

Aspect 17: The device of aspects 11 through 16, further comprising a second integrated device coupled to the substrate, wherein the lid frame is coupled to the second integrated device through another thermal interface material.

Aspect 18: The device of aspects 11 through 16, wherein the package further comprises a second integrated device, wherein the second integrated device is at least partially encapsulated by the second encapsulation layer, and wherein the lid frame is coupled to the second integrated device through another thermal interface material.

Aspect 19: The device of aspects 11 through 18, wherein the thermal interface material may touch the second encapsulation layer, and wherein the adhesive may touch the first integrated device.

Aspect 20: The device of aspects 11 through 19, wherein the package interposer further comprises at least one passive device and/or at least one bridge.

Aspect 21: The device of aspects 11 through 20, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a substrate;
a package coupled to the substrate, the package comprising:
a first integrated device; and
an encapsulation layer that at least partially encapsulates the first integrated device; and
a lid frame coupled to the substrate,
wherein the lid frame is further coupled to the first integrated device through
a thermal interface material, and
wherein the lid frame is further coupled to the encapsulation layer through an adhesive.

2. The device of claim 1,
wherein the thermal interface material touches the first integrated device and a first portion of the lid frame, and
wherein the adhesive touches the encapsulation layer and a second portion of the lid frame.

3. The device of claim 2, wherein the adhesive laterally surrounds the thermal interface material.

4. The device of claim 1, wherein the lid frame is coupled to the substrate through another thermal interface material.

5. The device of claim 1, wherein the lid frame is coupled to the substrate through another adhesive.

6. The device of claim 1, wherein the package comprises a package substrate coupled to the first integrated device and the encapsulation layer.

7. The device of claim 1, further comprising a second integrated device coupled to the substrate, wherein the lid frame is coupled to the second integrated device through another thermal interface material.

8. The device of claim 1, wherein the package further comprises a second integrated device,
wherein the second integrated device is at least partially encapsulated by the encapsulation layer, and
wherein the lid frame is coupled to the second integrated device through another thermal interface material.

9. The device of claim 1,
wherein the thermal interface material may touch the encapsulation layer, and
wherein the adhesive may touch the first integrated device.

10. The device of claim 1, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A device comprising:
a substrate;
a package coupled to the substrate, the package comprising:
a package interposer comprising:
a first metallization portion;
a first encapsulation layer coupled to the first metallization portion; and
a second metallization portion coupled to the first encapsulation layer;
a first integrated device coupled to the package interposer; and
a second encapsulation layer that at least partially encapsulates the first integrated device; and
a lid frame coupled to the substrate,
wherein the lid frame is further coupled to the first integrated device through a thermal interface material, and
wherein the lid frame is further coupled to the second encapsulation layer through an adhesive.

12. The device of claim 11,
wherein the thermal interface material touches the first integrated device and a first portion of the lid frame, and
wherein the adhesive touches the second encapsulation layer and a second portion of the lid frame.

13. The device of claim 12, wherein the adhesive laterally surrounds the thermal interface material.

14. The device of claim 11, wherein the lid frame is coupled to the substrate through another thermal interface material.

15. The device of claim 11, wherein the lid frame is coupled to the substrate through another adhesive.

16. The device of claim 11, wherein the package comprises a package substrate coupled to the first integrated device and the second encapsulation layer.

17. The device of claim 11, further comprising a second integrated device coupled to the substrate, wherein the lid frame is coupled to the second integrated device through another thermal interface material.

18. The device of claim 11, wherein the package further comprises a second integrated device,
wherein the second integrated device is at least partially encapsulated by the second encapsulation layer, and
wherein the lid frame is coupled to the second integrated device through another thermal interface material.

19. The device of claim 11,
wherein the thermal interface material may touch the second encapsulation layer, and
wherein the adhesive may touch the first integrated device.

20. The device of claim 11, wherein the package interposer further comprises at least one passive device and/or at least one bridge.
